(19) United States
(12) Patent Application Publication
(10) Pub. No.: US 2024/0178222 A1
(43) Pub. Date: May 30, 2024

(54) SEMICONDUCTOR DEVICE

(71) Applicant: RENESAS ELECTRONICS CORPORATION, Tokyo (JP)

(72) Inventors: Naohito SUZUMURA, Tokyo (JP); Eiji TSUKUDA, Tokyo (JP); Yoshiki YAMAMOTO, Tokyo (JP)

(21) Appl. No.: 18/483,737

(22) Filed: Oct. 10, 2023

(30) Foreign Application Priority Data
Nov. 24, 2022 (JP) 2022-187154

(51) Int. Cl. H01L 27/06; H01L 29/04; H01L 29/36

(52) U.S. Cl. CPC H01L 27/0629; H01L 29/04; H01L 29/36; H01L 29/665

(57) ABSTRACT

A resistance element is comprised of a first semiconductor layer of an SOI substrate and a second semiconductor layer formed on the first semiconductor layer. The second semiconductor layer has first and second semiconductor portions spaced apart from each other. The first semiconductor layer has a first region on which the first semiconductor portion is formed, a second region on which the second semiconductor portion is formed, and a third region on which no epitaxial semiconductor layer is formed. Each of the first region and the second region further has a low concentration region located next to the third region. An impurity concentration of the low concentration region is lower than an impurity concentration of the third region. Each semiconductor portion has a middle concentration region located on the low concentration region. An impurity concentration of the middle concentration region is higher than that of the low concentration region.

### CROSS-REFERENCE TO RELATED APPLICATIONS

The present application claims priority from Japanese Patent Application No. 2022-187154 filed on Nov. 24, 2022, the content of which is hereby incorporated by reference to this application.

### BACKGROUND

The present invention relates to a semiconductor device, for example, a technique effectively applied to a semiconductor device having a resistance element.

In order to manufacture a semiconductor device, there is a technique in which an element isolation region is formed on a semiconductor substrate and semiconductor elements such as a MISFET (Metal Insulator Semiconductor Field Effect Transistor) and a resistance element are formed in an active region of the semiconductor substrate defined by the element isolation region, and a multilayer wiring structure is formed on the semiconductor substrate. There is also a technique of using an SOI substrate as the semiconductor substrate.

Here, there are disclosed techniques listed below.
[Patent Document 1] Japanese Unexamined Patent Application Publication No. 2022-80908

Patent Document 1 discloses a technique of forming the resistance element by using a semiconductor layer of the SOI substrate.

### SUMMARY

If a resistance value of the resistance element provided in the semiconductor device is increased, an area required for arranging the resistance element in the semiconductor device increases. However, this invites the increase in the area of the semiconductor device, thereby becoming disadvantageous for miniaturization of the semiconductor device. It is desired to provide a technique capable of increasing the resistance value of the resistance element included in the semiconductor device without inviting the increase in the area of the semiconductor device.

Other problems and novel features will become apparent from the description of the present specification and the accompanying drawings.

According to one embodiment, a semiconductor device includes: a substrate; a resistance element formed in a first region of the substrate; and a MISFET formed in a second region of the substrate. The substrate has: a support substrate; an insulating layer on the support substrate; and a semiconductor layer on the insulating layer. The resistance element is comprised of: the semiconductor layer located in the first region; and first and second semiconductor portions formed on the semiconductor layer located in the first region so as to be spaced apart from each other. The semiconductor layer located in the first region has: a first connection portion on which the first semiconductor portion is formed; a second connection portion on which the second semiconductor portion is formed; and an element portion located between the first connection portion and the second connection portion, and on which no epitaxial semiconductor layer is formed. A conductivity type of each of the first semiconductor portion, the second semiconductor portion, the first connection portion, the second connection portion, and the element portion is a first conductivity type. Each of the first connection portion and the second connection portion has a first low concentration region located next to the element portion. Each of the first semiconductor portion and the second semiconductor portion has a first medium concentration region located on the first low concentration region. An impurity concentration of the first low concentration region of each of the first connection portion and the second connection portion is lower than an impurity concentration of the element portion. An impurity concentration of the first medium concentration region of each of the first semiconductor portion and the second semiconductor portion is higher than the impurity concentration of the first low concentration region.

According to one embodiment, the resistance value of the resistance element included in the semiconductor device can be increased without inviting the increase in the area of the semiconductor device.

### BRIEF DESCRIPTION OF THE DRAWINGS

FIG. 1 is a plan view of a main portion of a semiconductor device according to one embodiment.

FIG. 2 is a cross-sectional view of the main portion of the semiconductor device according to one embodiment.

FIG. 3 is a cross-sectional view of the main portion of the semiconductor device according to one embodiment.

FIG. 4 is a cross-sectional view of the main portion of the semiconductor device according to one embodiment.

FIG. 5 is a cross-sectional view of the main portion of the semiconductor device according to one embodiment.

FIG. 6 is a cross-sectional view of the main portion of the semiconductor device according to one embodiment.

FIG. 7 is a cross-sectional view of the main portion of the semiconductor device according to one embodiment.

FIG. 8 is a cross-sectional view of a resistance element according to one embodiment.

FIG. 9 is a cross-sectional view of the resistance element according to one embodiment.

FIG. 10 is a partially enlarged cross-sectional view enlarging a part of FIG. 7.

FIG. 11 is a cross-sectional view of the main portion of the semiconductor device according to one embodiment during a manufacturing process.

FIG. 12 is a cross-sectional view of the main portion of the semiconductor device during the manufacturing process following FIG. 11.

FIG. 13 is a cross-sectional view of the main portion of the semiconductor device during the manufacturing process following FIG. 12.

FIG. 14 is a cross-sectional view of the main portion of the semiconductor device during the manufacturing process following FIG. 13.

FIG. 15 is a cross-sectional view of the main portion of the semiconductor device during the manufacturing process following FIG. 14.

FIG. 16 is a cross-sectional view of the main portion of the semiconductor device during the manufacturing process following FIG. 15.

FIG. 17 is a cross-sectional view of the main portion of the semiconductor device during the manufacturing process following FIG. 16.

FIG. 18 is a cross-sectional view of the main portion of the semiconductor device during the manufacturing process following FIG. 17.

FIG. 19 is a cross-sectional view of the main portion of the semiconductor device during the manufacturing process following FIG. 18.

FIG. 20 is a cross-sectional view of the main portion of the semiconductor device during the manufacturing process following FIG. 19.

FIG. 21 is a cross-sectional view of the main portion of the semiconductor device during the manufacturing process following FIG. 20.

FIG. 22 is a cross-sectional view of the main portion of the semiconductor device during the manufacturing process following FIG. 21.

FIG. 23 is a cross-sectional view of the main portion of the semiconductor device during the manufacturing process following FIG. 22.

FIG. 24 is a cross-sectional view of the main portion of the semiconductor device during the manufacturing process following FIG. 23.

FIG. 25 is a cross-sectional view of the main portion of the semiconductor device during the manufacturing process following FIG. 24.

FIG. 26 is a cross-sectional view of the main portion of the semiconductor device during the manufacturing process following FIG. 25.

FIG. 27 is a partially enlarged cross-sectional view of a resistance element in a study example.

FIG. 28 is a graph showing a correlation between a sheet resistance of the resistance element and a length of an element portion of a semiconductor layer configuring the resistance element.

FIG. 29 is a graph showing the correlation between the sheet resistance of the resistance element and the length of the element portion of the semiconductor layer configuring the resistance element.

FIG. 30 is a partially enlarged cross-sectional view of a resistance element of a modification example.

FIG. 31 is a cross-sectional view of a main portion of a semiconductor device of the modification example during a manufacturing process.

FIG. 32 is a cross-sectional view of the main portion of the semiconductor device during the manufacturing process following FIG. 31.

FIG. 33 is a cross-sectional view of the main portion of the semiconductor device during the manufacturing process following FIG. 32.

FIG. 34 is a plan view of a main portion of a semiconductor device according to another embodiment.

FIG. 35 is a cross-sectional view of the main portion of the semiconductor device according to another embodiment.

FIG. 36 is a cross-sectional view of the main portion of the semiconductor device according to another embodiment during a manufacturing process.

FIG. 37 is a cross-sectional view of the main portion of the semiconductor device during the manufacturing process following FIG. 36.

FIG. 38 is a cross-sectional view of the main portion of the semiconductor device during the manufacturing process following FIG. 37.

FIG. 39 is a cross-sectional view of the main portion of the semiconductor device during the manufacturing process following FIG. 38.

FIG. 40 is a plan view of the main portion of the semiconductor device according to another embodiment.

FIG. 41 is a plan view of the main portion of the semiconductor device according to another embodiment.

FIG. 42 is a plan view of the main portion of the semiconductor device according to another embodiment.

FIG. 43 is a graph showing temperature dependence of the resistance value of the resistance element.

FIG. 44 is a plan view of the main portion of the semiconductor device according to another embodiment.

FIG. 45 is a cross-sectional view of the main portion of the semiconductor device according to another embodiment.

FIG. 46 is a cross-sectional view of the main portion of the semiconductor device according to another embodiment during the manufacturing process.

FIG. 47 is a cross-sectional view of the main portion of the semiconductor device during the manufacturing process following FIG. 46.

FIG. 48 is a cross-sectional view of the main portion of the semiconductor device during the manufacturing process following FIG. 47.

FIG. 49 is a cross-sectional view of the main portion of the semiconductor device during the manufacturing process following FIG. 48.

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle, and the number larger or smaller than the specified number is also applicable. Further, in the embodiments described below, it goes without saying that the components (including element steps) are not always indispensable unless otherwise stated or except the case where the components are apparently indispensable in principle. Also, even when mentioning that constituent elements or the like are “made of A” or “made up of A” in the embodiments below, elements other than A are of course not excluded except the case where it is particularly specified that A is the only element thereof. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, embodiments of the present invention will be described in detail with reference to the accompanying drawings. Note that components having the same function are denoted by the same reference characters throughout the drawings for describing the embodiments, and the repetitive description thereof will be omitted. In addition, the description of the same or similar portions is not repeated in principle unless particularly required in the following embodiments.

Also, in some drawings used in the following embodiments, hatching is omitted even in a cross-sectional view so as to make the drawings easy to see. In addition, hatching is used even in a plan view so as to make the drawings easy to see.

### First Embodiment

### <Regarding Structure of Semiconductor Device>

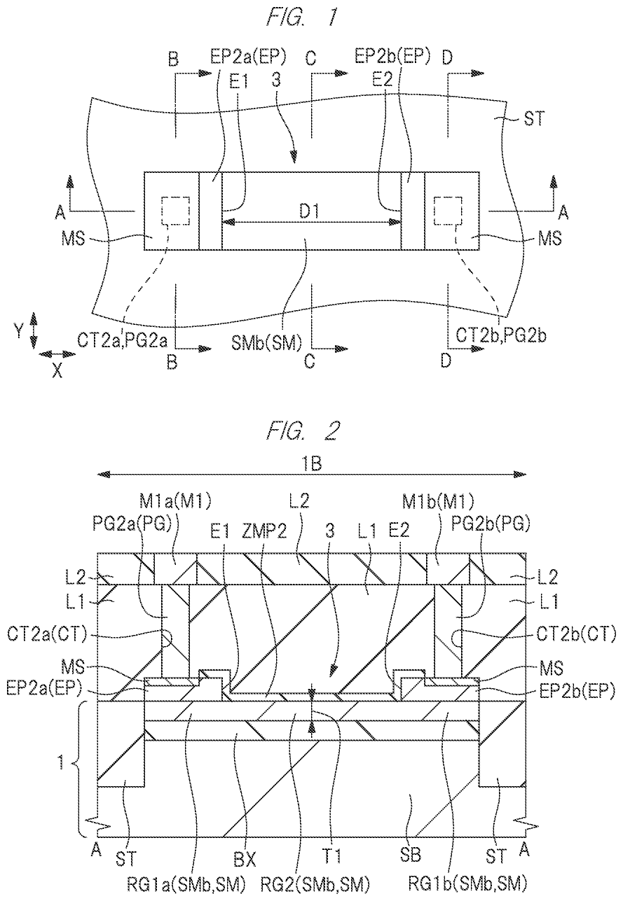

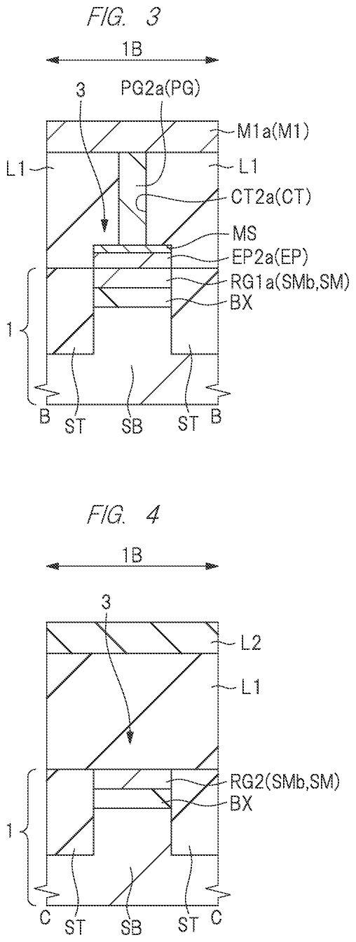

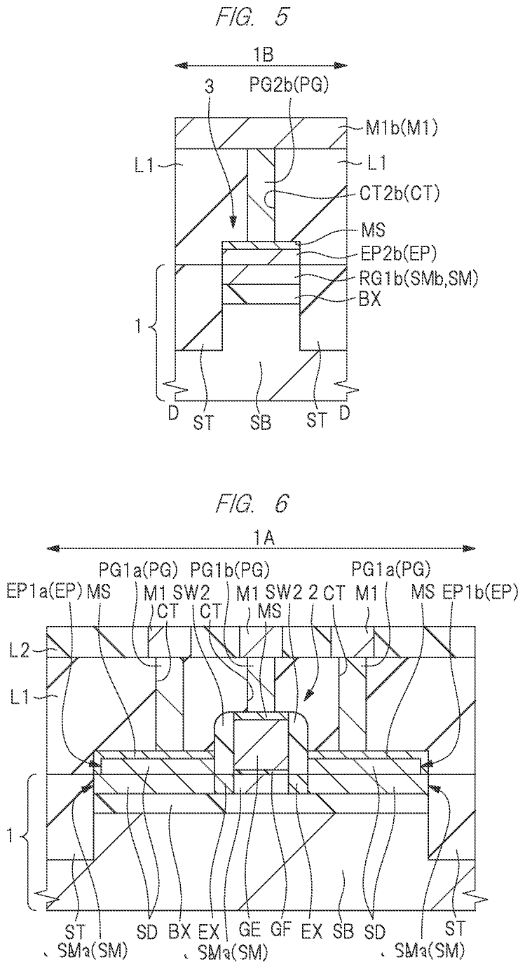

A semiconductor device of the present embodiment will be described with reference to the drawings. FIG. 1 is a plan view of a main portion of a semiconductor device of the present embodiment, and FIGS. 2 to 6 are cross-sectional views of the main portion of the semiconductor device of the present embodiment. The cross-sectional view taken along line A-A in FIG. 1 substantially corresponds to FIG. 2; the cross-sectional view taken along line B-B in FIG. 1 substantially corresponds to FIG. 3; the cross-sectional view taken along line C-C in FIG. 1 substantially corresponds to FIG. 4; and the cross-sectional view taken along line D-D of FIG. 1 substantially corresponds to FIG. 5. Consequently, FIGS. 2 to 5 are cross-sectional views substantially perpendicular to a main surface of an SOI substrate 1. FIGS. 1 to 5 correspond to plan views and cross-sectional views of a resistance element formation region 1B in which a resistance element 3 is formed, and FIG. 6 corresponds to a cross-sectional view of a MISFET formation region 1A in which a MISFET 2 is formed. Further, an X direction, a Y direction, and a Z direction shown in FIGS. 1 to 5 are directions perpendicular to one another, but the X direction and the Y direction are directions substantially parallel to the main surface of the SOI substrate 1 and the Z direction is a direction substantially perpendicular to the main surface of the SOI substrate 1.

The semiconductor device of the present embodiment shown in FIGS. 1 to 6 is a semiconductor device using an SOI (Silicon On Insulator) substrate 1.

As shown in FIGS. 2 to 6, the SOI substrate 1 includes a semiconductor substrate (support substrate) SB as a support substrate, an insulating layer (buried insulating film) BX formed on a main surface of the semiconductor substrate SB, and a semiconductor layer SM formed on an upper surface of the insulating layer BX. The semiconductor substrate SB is the support substrate, which supports the insulating layer BX and a structure on and above the insulating layer BX, but is also a semiconductor substrate.

The semiconductor substrate SB is preferably a single crystal silicon substrate, and is made of, for example, p-type single crystal silicon. For example, the semiconductor substrate SB can be formed of single crystal silicon having a resistivity of about 1Ω to 10 Ωcm. A thickness of the semiconductor substrate SB can be, for example, about 700 μm to 750 μm. The insulating layer BX is preferably a silicon oxide film, and a thickness of the insulating layer BX can be, for example, about 10 nm to 20 nm. When the insulating layer BX is a silicon oxide film, the insulating layer BX can also be regarded as a buried oxide film, that is, a BOX (Buried Oxide) layer. The semiconductor layer SM is made of single crystal silicon or the like. For example, the semiconductor layer SM can be formed of single crystal silicon having a resistivity of about 1Ω to 10 Ωcm. The semiconductor layer SM can also be regarded as an SOI layer. The thickness of the semiconductor layer SM is thinner than the thickness of the semiconductor substrate SB that is the support substrate, and the thickness of the semiconductor layer SM can be, for example, about 15 nm to 25 nm. The SOI substrate 1 is formed by the semiconductor substrate SB, the insulating layer BX, and the semiconductor layer SM.

As shown in FIGS. 2 to 6, element isolation regions (element isolation structures) ST are formed in the SOI substrate 1. The element isolation region ST is formed of an insulating film (for example, a silicon oxide film) embedded in an element isolation trench (trench for element isolation). The element isolation trench and the element isolation region ST filling it penetrate through the semiconductor layer SM and the insulating layer BX, and their bottom portions reach halfway the thickness of the semiconductor substrate SB. That is, the element isolation region ST becomes embedded in the element isolation trench formed over the semiconductor layer SM, the insulating layer BX, and the semiconductor substrate SB.

The SOI substrate 1 of the present embodiment has a MISFET formation region 1A in which the MISFET is formed and a resistance element formation region 1B in which the resistance element is formed. The MISFET formation region 1A and the resistance element formation region 1B correspond to mutually different planar regions on the same main surface of the SOI substrate 1. The MISFET formation region 1A and the resistance element formation region 1B are each partitioned by the element isolation region ST and, for example as shown in FIG. 1, are surrounded by the element isolation region ST. Therefore, each of the MISFET formation region 1A and the resistance element formation region 1B can be regarded as an active region surrounded by the element isolation region ST.

A MISFET (Metal Insulator Semiconductor Field Effect Transistor) 2 is formed on the semiconductor layer SM in the MISFET formation region 1A. The resistance element 3 is formed of the semiconductor layer SM in the resistance element formation region 1B. In the SOI substrate 1, the semiconductor layer SM in the MISFET formation region 1A and the semiconductor layer SM in the resistance element formation region 1B are planarly surrounded and partitioned by the element isolation regions ST.

Here, the semiconductor layer SM in the MISFET formation region 1A is denoted by the symbol SMa and referred to as a semiconductor layer SMa, and the semiconductor layer SM in the resistance element formation region 1B is denoted by the symbol SMb and referred to as a semiconductor layer SMb. The semiconductor layer SMa and the semiconductor layer SMb have the same thickness as each other. Incidentally, the term “same” as used herein means that two or more objects (here, “thicknesses”) to be compared are substantially the same. That is, it means that the two or more objects to be compared are the same in design as each other, but are not necessarily the same in actual manufactured products due to manufacturing variations.

The semiconductor layer SM in the MISFET formation region 1A, that is, the semiconductor layer SMa is surrounded by the insulating layer BX and the element isolation region ST since its side surface contacts with the element isolation region ST and its bottom portion contacts with the insulating layer BX. That is, the bottom portion of the semiconductor layer SMa is covered with the insulating layer BX, and the side surface of the semiconductor layer SMa is covered with the element isolation region ST. In addition, the semiconductor layer SM in the resistance element formation region 1B, that is, the semiconductor layer SMb is surrounded by the insulating layer BX and the element isolation region ST since its side surface contacts with the element isolation region ST and its bottom portion contacts with the insulating layer BX. That is, the bottom portion of the semiconductor layer SMb is covered with the insulating layer BX, and the side surface of the semiconductor layer SMb is covered with the element isolation region ST. The semiconductor layer SMa and the semiconductor layer SMb are each surrounded by the element isolation region ST in a plan view and, therefore, are spaced apart from each other by the element isolation region ST.

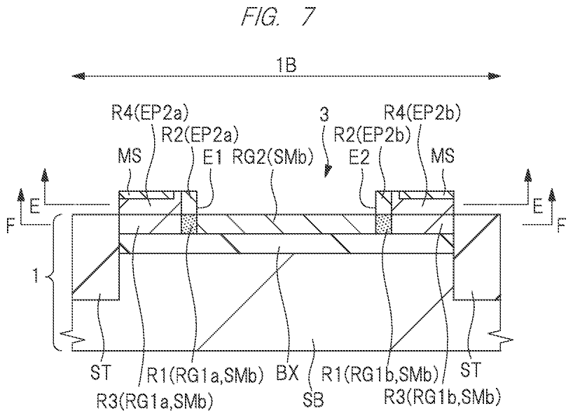

First, the MISFET 2 formed in the MISFET formation region 1A will be described (see FIG. 8).

The MISFET 2 has a gate electrode GE formed over the semiconductor layer SMa via a gate insulating film GF. The gate electrode GE is made of polycrystalline silicon, for example. A sidewall spacer SW2 is formed as a sidewall insulating film on a sidewall of the gate electrode GE.

Semiconductor layers (epitaxial semiconductors) EP are formed on regions of the semiconductor layer SMa, which are located on both sides of a structure made of the gate electrode GE and the sidewall spacer SW2. That is, the semiconductor layer EP is formed on a region of the semiconductor layer SMa, which is not covered with the gate electrode GE and the sidewall spacer SW2. The semiconductor layer EP is an epitaxial semiconductor layer formed by epitaxial growth, and is made of, for example, silicon (single crystal silicon).

Here, one of the semiconductor layers EP formed on both sides of the structure made of the gate electrode GE and the sidewall spacer SW2 is referred to as a semiconductor portion (epitaxial semiconductor portion) EP1a, and the other is referred to as a semiconductor portion (epitaxial semiconductor portion) EP1b. That is, the semiconductor layer EP formed on the semiconductor layer SMa has the semiconductor portions EP1a and EP1b formed separately from each other on the semiconductor layer SMa. The semiconductor portion EP1a and the semiconductor portion EP1b are spaced apart from each other with the gate electrode GE and the sidewall spacer SW2 interposed therebetween. Therefore, the semiconductor portion EP1a and the semiconductor portion EP1b are made of the same material (here, single crystal silicon) as each other and have the same thickness as each other. The gate electrode GE is arranged between the semiconductor portion EP1a and the semiconductor portion EP1b in a plan view.

In the MISFET formation region 1A, a source/drain region (semiconductor region for source or drain) of the MISFET 2 is formed in each of the semiconductor layers EP and SMa. Specifically, a semiconductor region EX formed on the semiconductor layer SMa, and a semiconductor region SD formed over the semiconductor layer EP and the semiconductor layer SMa form the source/drain region of an LDD (Lightly Doped Drain) structure. An impurity concentration in the semiconductor region SD is higher than an impurity concentration in the semiconductor region EX. Incidentally, in the present embodiment, the semiconductor region EX formed in the semiconductor layer SMa is, for example, a p-type semiconductor region. Further, the semiconductor region SD formed over the semiconductor layer EP and the semiconductor layer SMa is also a p-type semiconductor region like the semiconductor region EX. That is, the MISFET 2 of the present embodiment is a p-channel MISFET.

In the MISFET formation region 1A, the p⁻-type semiconductor region EX is formed in a region located directly under the sidewall spacer SW2 in the semiconductor layer SMa. In the MISFET formation region 1A, the p⁺-type semiconductor region SD is formed over the semiconductor layer EP and a region of the semiconductor layer SMa located below the semiconductor layer EP. A region of the semiconductor layer SMa located directly under the gate electrode GE becomes a channel formation region of the MISFET 2. The p⁻-type semiconductor regions EX are formed on both sides (both sides in a gate length direction) of the channel formation region so that the p⁻-type semiconductor regions EX contact with the channel formation region. Therefore, a PN junction is formed between the channel formation region of the MISFET 2 and the semiconductor region EX. In addition, the p⁺-type semiconductor region SD is adjacent to the p⁻-type semiconductor region EX, and the p⁻-type semiconductor region EX is interposed between the p⁺-type semiconductor region SD and the channel formation region. Incidentally, as described above, since the MISFET 2 of the present embodiment is an p-channel type MISFET, the PN junction is formed between the channel formation region of the MISFET 2 and the semiconductor region EX.

Incidentally, one of the two (a pair of) p⁺-type semiconductor regions SD, which are formed on both sides of the gate electrode GE and the sidewall spacer SW2, is a source region configuring the MISFET 2, and the other thereof is a drain region configuring the MISFET 2. The p⁺-type semiconductor region SD configuring the source region is formed over the semiconductor portion EP1a and the underlying semiconductor layer SMa, and the p⁺-type semiconductor region SD configuring the drain region is formed over the semiconductor portion EP1b and the underlying semiconductor layer SMa.

A metal silicide layer (metal compound layer) MS is formed on a surface (upper layer portion) of each of the gate electrode GE and the p⁺-type semiconductor region SD. More specifically, the metal silicide layer MS is formed on the surface (upper layer portion) of the semiconductor layer EP (semiconductor portions EP1a, EP1a) configuring the p⁺-type semiconductor region SD.

Next, the resistance element 3 formed in the resistance element formation region 1B will be described (see FIGS. 1 to 5).

The semiconductor layer (epitaxial semiconductor) EP is formed on the semiconductor layer SMb. In the resistance element formation region 1B, the semiconductor layer EP is not formed over the entire semiconductor layer SMb but partially formed over the semiconductor layer SMb. The semiconductor layer EP is an epitaxial semiconductor layer formed by epitaxial growth, and is made of, for example, silicon (single crystal silicon).

The semiconductor layer EP formed on the semiconductor layer SMb has semiconductor portions (epitaxial semiconductor portions) EP2a and EP2b spaced apart from each other. Therefore, the semiconductor portion EP2a and the semiconductor portion EP2b are formed by epitaxial growth, are made of the same material (here, single crystal silicon) as each other, and have the same thickness as each other.

The semiconductor layers EP (respective semiconductor portions EP2a and EP2b) formed in the resistance element formation region 1B and the semiconductor layers EP (respective semiconductor portions EP1a and EP1b) formed in the MISFET formation region 1A are formed in the same process (same epitaxial growth process). Therefore, the semiconductor layers EP (respective semiconductor portions EP2a and EP2b) formed in the resistance element formation region 1B and the semiconductor layers EP (respective semiconductor portions EP1a and EP1b) formed in the MISFET formation region 1A are made of the same material (here single crystal silicon) as each other and have the same thickness as each other.

The resistance element 3 is comprised of the semiconductor layer SMb and the semiconductor layer EP (semiconductor portions EP2a and EP2b) formed on the semiconductor layer SMb. If the semiconductor layers SMb and EP are made of silicon, the resistance element 3 can be regarded as a silicon resistance element.

In a case of FIGS. 1 to 7, the semiconductor portion EP2a is formed on the semiconductor layer SMb at one end in an extension direction (X direction) of the semiconductor layer SMb, and the semiconductor portion EP2b is formed on the semiconductor layer SMb at the other end in the extension direction (X direction) of the semiconductor layer SMb. The semiconductor portion EP2a and the semiconductor portion EP2b are spaced apart from each other.

The semiconductor layer SMb integrally has a region (connection portion, end) RG1a located directly under the semiconductor portion EP2a, a region (connection portion, end) RG1b located directly under the semiconductor portion EP2b, and a region (element portion, center portion) RG2 which is located between the region RG1a and the region RG1b and on which the semiconductor layer EP is not formed. In the semiconductor layer SMb, the semiconductor portion EP2a is formed on the region RG1a, and the semiconductor portion EP2b is formed on the region RG1b, but the semiconductor layer EP is not formed on the region RG2. The region RG1a can be regarded as a region of the semiconductor layer SMb on which the semiconductor portion EP2a is formed, the region RG1b can be regarded as a region of the semiconductor layer SMb on which the semiconductor portion EP2b is formed, and then the region RG2 can be regarded as a region of the semiconductor layer SMb on which the semiconductor layer EP is not formed.

A metal silicide layer (metal compound layer) MS is formed on each surface (upper layer portion) of the semiconductor portion EP2a and the semiconductor portion EP2b. What corresponds to the metal silicide layer MS is not formed on the surface of the semiconductor layer SMb. In the semiconductor layer SMb, a surface (upper surface) of the region RG2 that is not covered with the semiconductor layer EP (respective semiconductor portions EP2a and EP2b) is covered with an insulating film pattern (patterned insulating film) ZMP2. In addition, in the surface (upper surface) of each of the semiconductor portions EP2a and EP2b, the regions in which the metal silicide layer MS is not formed are also covered with the insulating film pattern ZMP2. Further, the insulating film patterns ZMP2 are formed on side surfaces (opposed side surfaces to each other) of the respective semiconductor portions EP2a and EP2b so that the insulating film pattern ZMP2 on the surface of the semiconductor layer SMb located in the region RG2 and the insulating film pattern ZMP2 on the surface of each of the semiconductor portions EP2a and EP2b are mutually and integrally connected. Therefore, the metal silicide layer MS is formed in the region that is not covered with the insulating film pattern ZMP2 in the surface of the each of the semiconductor portion EP2a and EP2b, and the insulating film pattern ZMP2 functions as a silicide block layer for preventing the metal silicide layer MS from being formed.

On the main surface of SOI substrate 1, an insulating film (interlayer insulating film) L1 is formed as an interlayer insulating film so as to cover the gate electrode GE, the sidewall spacer SW2, the semiconductor layers SM and EP, and the metal silicide layer MS. A contact hole (through hole, hole) CT penetrating through the insulating film L1 is formed in the insulating film L1, and a conductive plug (contact plug) PG is formed (embedded) in the contact hole CT. The plug PG is formed so as to be two or more in umber, and includes a plug PG (hereinafter, referred to as PG1b) connected to the gate electrode GE, a plug PG (hereinafter, referred to as PG1a) connected to the p⁺-type semiconductor region SD, a plug PG (hereinafter, referred to as PG2a) connected to the semiconductor portion EP2a, and a plug PG (hereinafter, referred to as PG2b) connected to the semiconductor portion EP2b. A bottom portion of each plug PG contacts with the metal silicide layer MS. Further, the contact hole CT in which the plug PG2a is embedded is hereinafter referred to as a contact hole CT2a, and the contact hole CT in which the plug PG2b is embedded is hereinafter referred to as a contact hole CT2b.

The plug PG1a contacts with the metal silicide layer MS formed on the surface of the p⁺-type semiconductor region SD, and is electrically connected to the p⁺-type semiconductor region SD via the metal silicide layer MS. Further, the plug PG1b contacts with the metal silicide layer MS formed on the surface of the gate electrode GE, and is electrically connected to the gate electrode GE via the metal silicide layer MS. Furthermore, the plug PG2a is arranged on the semiconductor portion EP2a, contacts with the metal silicide layer MS formed on the surface (upper layer portion) of the semiconductor portion EP2a, and is electrically connected to the semiconductor portion EP2a via the metal silicide layer MS. In addition, the plug PG2b is arranged on the semiconductor portion EP2b, contacts with the metal silicide layer MS formed on the surface (upper layer portion) of the semiconductor portion EP2b, and is electrically connected to the semiconductor portion EP2b via the metal silicide layer MS.

An insulating film L2 is formed on the insulating film L1 in which the plug PG is embedded, and a wiring M1 is formed (embedded) in a trench (wiring trench) formed in the insulating film L2. The wiring M1 is electrically connected to the p⁺-type semiconductor region SD, the gate electrode GE, the semiconductor portion EP2a, or the semiconductor portion EP2b via the plug PG.

Here, the wiring M1 connected to the plug PG2a is hereinafter referred to as a wiring M1a. Further, the wiring M1 connected to the plug PG2b is hereinafter referred to as a wiring M1b. The wiring M1a is electrically connected to the metal silicide layer MS on the surface of the semiconductor portion EP2a via the plug PG2a, and is further electrically connected to the semiconductor portion EP2a via the metal silicide layer MS. In addition, the wiring M1b is electrically connected to the metal silicide layer MS on the surface of the semiconductor portion EP2b via the plug PG2b, and is further electrically connected to the semiconductor portion EP2b via the metal silicide layer MS.

Wirings in layers above the wirings M1 are also formed, but here illustration and description of a structure above the insulating film L2 and the wirings M1 will be omitted.

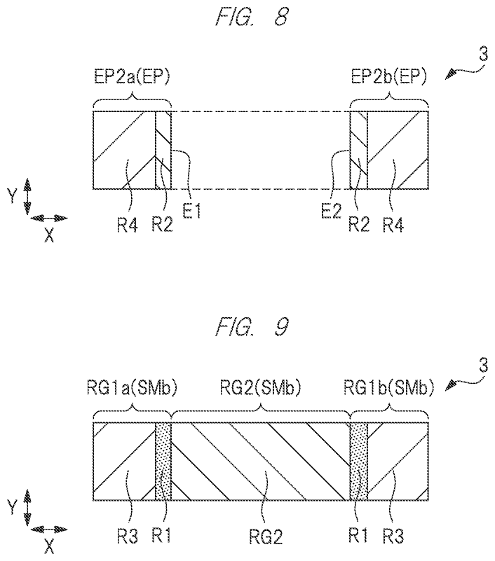

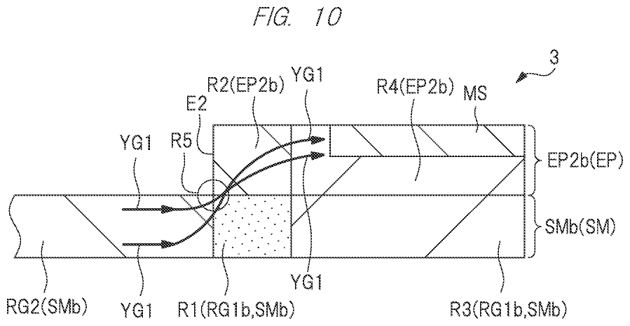

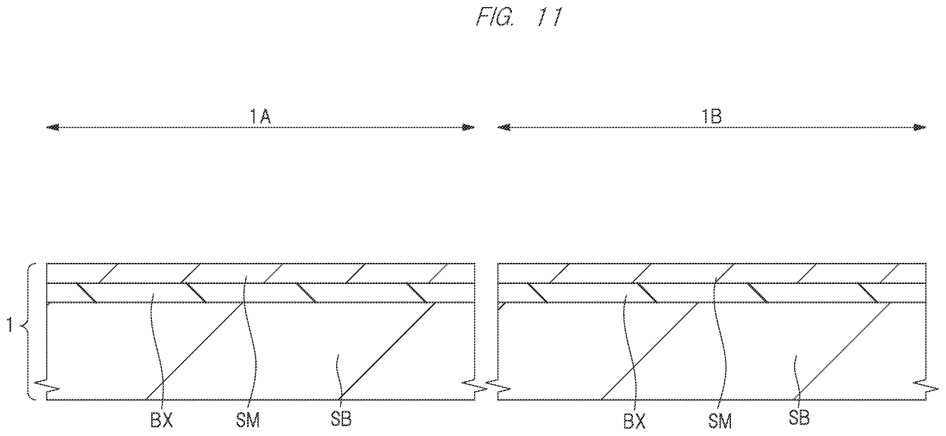

Next, an impurity concentration distribution in the semiconductor layer SMb and the semiconductor portions EP2a and EP2b, which configure the resistance element 3, will be described with reference to FIG. 2 and FIGS. 7 to 10. FIG. 7 is a cross-sectional view of the main portion of the semiconductor device of the present embodiment, and shows the same cross-section as FIG. 2, but FIG. 7 shows a plurality of regions R1, R2, R3, and R4 mutually different in impurity concentration (however, the impurity concentrations in the regions R3 and R4 are the same) in the semiconductor layer SMb and the respective semiconductor portions EP2a and EP2b configuring the resistance element 3. By comparing FIG. 2 and FIG. 7, it can be understood which regions of the semiconductor layer SMb and the respective semiconductor portions EP2a and EP2b configuring the resistance element 3 have what impurity concentrations. In addition, FIGS. 8 and 9 are cross-sectional views of the resistance element 3 of the embodiment. FIGS. 8 and 9 show cross-sections substantially parallel to the main surface of the SOI substrate 1, but the cross-sectional view taken along line E-E in FIG. 7 substantially corresponds to FIG. 8, the cross-sectional view taken along line F-F in FIG. 7 substantially corresponds to FIG. 9. Also, FIG. 10 is a partially enlarged cross-sectional view enlarging a part of FIG. 7, and shows a part of the resistance element 3.

A conductivity type of each of the semiconductor layer SMb and the respective semiconductor portions EP2a and EP2b configuring the resistance element 3 is the same conductivity type (here, p-type) as each other. That is, the conductivity type of each of the semiconductor portion EP2a, the semiconductor portion EP2b, the region (connection portion, end) RG1a, the region (connection portion, end) RG1b, and the region (element portion, center portion) RG2 are the same conductivity type (here, p-type) as each other. Therefore, the respective conductivity types of the regions R1, R2, R3, and R4 are also the same conductivity type (here, p-type). Incidentally, as described above, in the present embodiment, the respective regions R1, R2, R3, R4, and RG2 configuring the resistance element 3 have the same conductivity type as each other, so that no PN junction is formed between the two adjacent regions among the respective regions R1, R2, R3, R4, and RG2.

The impurity concentration (p-type impurity concentration) in the region R3 is higher than the impurity concentration (p-type impurity concentration) in each of the regions R1 and R2. Further, the impurity concentration (p-type impurity concentration) in the region R4 is higher than the impurity concentration (p-type impurity concentration) in each of the regions R1 and R2. Also, the impurity concentration (p-type impurity concentration) in the region R2 is higher than the impurity concentration (p-type impurity concentration) in the region R1. The impurity concentration (p-type impurity concentration) in the region R3 and the impurity concentration (p-type impurity concentration) in the region R4 are the same as each other. Therefore, the regions R3 and R4 among the regions R1, R2, R3, and R4 each have the highest impurity concentration (p-type impurity concentration). Further, the region R1 among the regions R1, R2, R3, and R4 has the lowest impurity concentration (p-type impurity concentration). In consideration of the above points, the region R3 is hereinafter referred to as the high density region R3, the region R4 is referred to as the high density region R4, the region R2 is referred to as the medium density region R2, and the region R1 is referred to as the low density region R1. Incidentally, the term “same” as used herein means that two or more objects to be compared (here, “impurity concentration”) are substantially the same. That is, it means that the two or more objects to be compared are the same in design as each other, but are not necessarily the same in the actual manufactured products due to the manufacturing variations.

In the present embodiment, the impurity concentration (p-type impurity concentration) in the region RG2 of the semiconductor layer SMb is lower than the impurity concentration (p-type impurity concentration) in each of the high concentration regions R3 and R4, and is higher than the impurity concentration (p-type impurity concentration) in the low concentration region R1. More specifically, the impurity concentration (p-type impurity concentration) in the region RG2 of the semiconductor layer SMb and the impurity concentration (p-type impurity concentration) in the middle concentration region R2 are the same as each other. The impurity concentration in the region RG2 of the semiconductor layer SMb is substantially uniform. Incidentally, the term “same” as used herein means that two or more objects to be compared (here, “impurity concentration”) are substantially the same. That is, it means that the two or more objects to be compared are the same in design, but are not necessarily the same in the actual manufactured products due to the manufacturing variations.

Each of the region RG1a of the semiconductor layer SMb and the region RG1b of the semiconductor layer SMb is comprised of the low concentration region R1 and the high concentration region R3. Further, each of the semiconductor portion EP2a and the semiconductor portion EP2b is comprised of the middle concentration region R2 and the high concentration region R4.

In the region RG1a of the semiconductor layer SMb, the low concentration region R1, and the high concentration region R3 are adjacent to each other in the X direction. Further, the low concentration region R1 in the region RG1a of the semiconductor layer SMb is located next to the region RG2 of the semiconductor layer SMb so that the low concentration region R1 contacts with the region RG2 of the semiconductor layer SMb. That is, the low concentration region R1 in the region RG1a of the semiconductor layer SMb is interposed between the high concentration region R3 in the region RG1a of the semiconductor layer SMb and the region RG2 of the semiconductor layer SMb. In addition, in the semiconductor portion EP2a, the middle concentration region R2 and the high concentration region R4 are adjacent to each other in the X direction. The medium concentration region R2 of the semiconductor portion EP2a is located on the low concentration region R1 in the region RG1a of the semiconductor layer SMb, and the high concentration region R4 of the semiconductor portion EP2a is located on the high concentration region R3 in the region RG1a of the semiconductor layer SMb. Therefore, the medium concentration region R2 of the semiconductor portion EP2a and the low concentration region R1 in the region RG1a of the semiconductor layer SMb vertically overlap (match), and the high concentration region R4 of the semiconductor portion EP2a and the high concentration region R3 in the region RG1a of the semiconductor layer SMb vertically overlap (match).

In the region RG1b of the semiconductor layer SMb, the low concentration region R1 and the high concentration region R3 are adjacent to each other in the X direction. In addition, the low concentration region R1 in the region RG1b of the semiconductor layer SMb is located next to the region RG2 of the semiconductor layer SMb so that the low concentration region R1 contacts with the region RG2 of the semiconductor layer SMb. That is, the low concentration region R1 in the region RG1b of the semiconductor layer SMb is interposed between the high concentration region R3 in the region RG1b of the semiconductor layer SMb and the region RG2 of the semiconductor layer SMb. Further, in the semiconductor portion EP2b, the medium concentration region R2 and the high concentration region R4 are adjacent to each other in the X direction. The medium concentration region R2 of the semiconductor portion EP2b is located on the low concentration region R1 in the region RG1b of the semiconductor layer SMb, and the high concentration region R4 of the semiconductor portion EP2b is located on the high concentration region R3 in the region RG1b of the semiconductor layer SMb. Therefore, the middle concentration region R2 of the semiconductor portion EP2b and the low concentration region R1 in the region RG1b of the semiconductor layer SMb vertically overlap (match), and the high concentration region R4 of the semiconductor portion EP2b and the high concentration region R3 in the region RG1b of the semiconductor layer SMb vertically overlap (match).

Here, the semiconductor portion EP2a has an end (side surface) E1 opposing the semiconductor portion EP2b, and the semiconductor portion EP2b has an end (side surface) E2 opposing the semiconductor portion EP2a. The end E1 of the semiconductor portion EP2a and the end E2 of the semiconductor portion EP2b oppose each other and, in a case of FIG. 1, oppose each other in the X direction. The medium concentration region R2 of the semiconductor portion EP2a is a region near the end E1 of the semiconductor portion EP2a, and reaches the end E1 of the semiconductor portion EP2a. Further, the medium concentration region R2 of the semiconductor portion EP2b is a region near the end E2 of the semiconductor portion EP2b, and reaches the end E2 of the semiconductor portion EP2b.

Although details will be described later, the medium concentration region R2 corresponds to a region into which the p-type impurities are introduced in an ion implantation process for forming the p⁻-type semiconductor region EX, but which the p-type impurities have been not introduced in an ion implantation process for forming the p⁺-type semiconductor region SD. Further, the high concentration regions R3 and R4 correspond to regions into which the p-type impurities are introduced in the ion implantation process for forming the p⁺-type semiconductor region SD. Furthermore, the low concentration region R1 corresponds to a region into which the p-type impurities are not introduced in the ion implantation process for forming the p⁻-type semiconductor region EX and which the type impurities have not been introduced in the ion implantation process for forming the p⁺-type semiconductor region SD. Therefore, the impurity concentration (p-type impurity concentration) in the medium concentration region R2 is the same as the impurity concentration (p-type impurity concentration) in the p⁻-type semiconductor region EX, and the impurity concentration of each of the high concentration regions R3 and R4 is the same as the impurity concentration (p-type impurity concentration) of the p⁺-type semiconductor region SD. Incidentally, the term “same” as used herein means that two or more objects to be compared (here, “impurity concentration”) are substantially the same. That is, it means that the two or more objects to be compared are the same in the design, but are not necessarily the same in the actual manufactured products due to the manufacturing variations.

Next, an operation of the resistance element 3 will be explained.

The resistance element 3 is formed of a semiconductor layer SM (that is, semiconductor layer SMb) in the resistance element formation region 1B and a semiconductor layer EP (specifically, semiconductor portions EP2a and EP2b) formed on the semiconductor layer SMb. A predetermined potential (voltage) is applied to the metal silicide layer MS on the surface of the semiconductor portion EP2a from the wiring M1a via the plug PG2a. Further, a predetermined potential (voltage) is applied to the silicide layer MS on the surface of the semiconductor portion EP2b from the wiring M1b via the plug PG2b. If there is a difference between the potential (voltage) of the wiring M1a and the potential (voltage) of the wiring M1b, that is, if there is a difference between the potential (voltage) of the plug PG2a and the potential (voltage) of the plug PG2b, a current flows in the resistance element 3. For example, when the potential (voltage) of the wiring M1a is higher than the potential (voltage) of the wiring M1b, a high potential (high voltage) is applied from the plug PG2a to the metal silicide layer MS on the surface of the semiconductor portion EP2a, and a low potential (low voltage) is applied from the plug PG2b to the metal silicide layer MS on the surface of the semiconductor portion EP2b. As a result, the current flows in the plug PG2b via the metal silicide layer MS on the surfaces of the semiconductor portion EP2a, the semiconductor portion EP2a, the semiconductor layer SMb, the semiconductor portion EP2b, and the metal silicide layer MS on the surface of the semiconductor portion EP2b in this order from the plug PG2a. Further, when the potential (voltage) of the wiring M1b is higher than the potential (voltage) of the wiring M1a, a high potential (high voltage) is applied from the plug PG2b to the metal silicide layer MS on the surface of the semiconductor portion EP2b and a low potential (low voltage) is applied from the plug PG2a to the metal silicide layer MS on the surface of the semiconductor portion EP2a. As a result, the current flows in the plug PG2a via the metal silicide layer MS on the surfaces of the semiconductor portion EP2b, the semiconductor portion EP2b, the semiconductor layer SMb, the semiconductor portion EP2a, and the metal silicide layer MS on the surface of the semiconductor portion EP2a in this order from the plug PG2b.

What mainly determines the resistance value of the resistance element 3 is the region RG2 of the semiconductor layer SMb. This is because since a thickness of the region RG2 of the semiconductor layer SMb is thin, a cross-sectional area of the region RG2 of the semiconductor layer SMb substantially perpendicular to a direction in which the current flows become small. By reducing the thickness of the region RG2 of the semiconductor layer SMb, the resistance value of the resistance element 3 can be increased. In addition, the resistance value of the resistance element 3 is also defined by the impurity concentration in the region RG2 (middle concentration region R2) of the semiconductor layer SMb. If the impurity concentration in the region RG2 of the semiconductor layer SMb is low, the resistance value of the resistance element 3 increases and if the impurity concentration in the region RG2 of the semiconductor layer SMb is high, the resistance value of the resistance element 3 decreases.

Incidentally, in the present embodiment, the MISFET 2 is a p-channel MISFET, and the conductivity type of each of the semiconductor layer SMb and the semiconductor layer EP (respective semiconductor portions EP2a and EP2b) configuring the resistance element 3 is a p-type. By reversing all the conductivity types, the MISFET 2 may be an n-channel MISFET, and the conductivity type of each of the semiconductor layer SMb and the semiconductor layer EP (respective semiconductor portions EP2a and EP2b) configuring the resistance element 3 may be an n-type.

### <Regarding Manufacturing Process of Semiconductor Device>

A manufacturing process of the semiconductor device of the present embodiment will be described with reference to the drawings. FIGS. 11 to 26 are cross-sectional views of the main portion of the semiconductor device of the present embodiment during the manufacturing process. Each of FIGS. 11 to 26 shows a cross-section corresponding to FIG. 6 (a cross-section of the MISFET formation region 1A) and cross-sections corresponding to FIGS. 2 and 7 (a cross-section of the resistance element formation region 1B).

First, as shown in FIG. 11, the SOI substrate 1 is prepared. As can be seen from FIG. 11, the SOI substrate 1 includes the semiconductor substrate SB as the support substrate, the insulating layer BX formed on the main surface of the semiconductor substrate SB, and the semiconductor layer SM formed over the upper surface of the insulating layer BX.

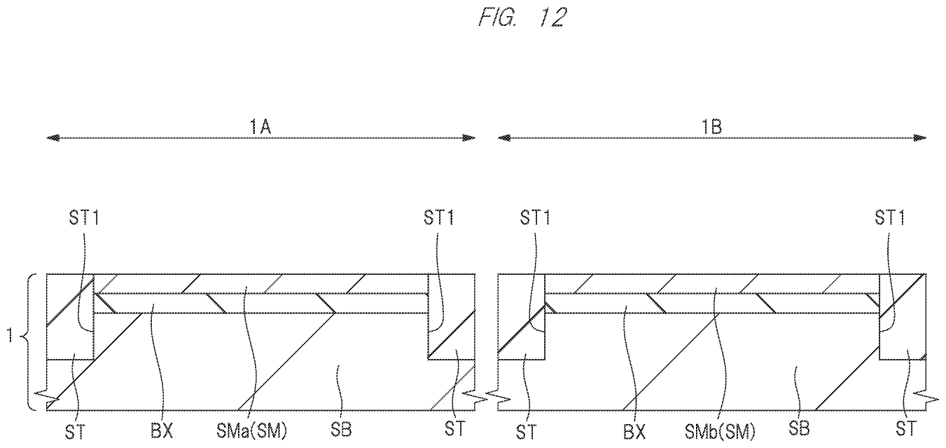

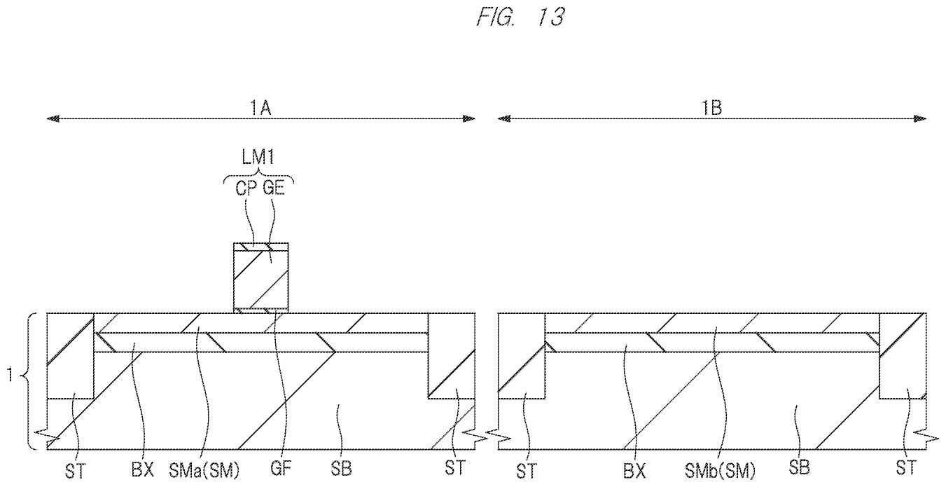

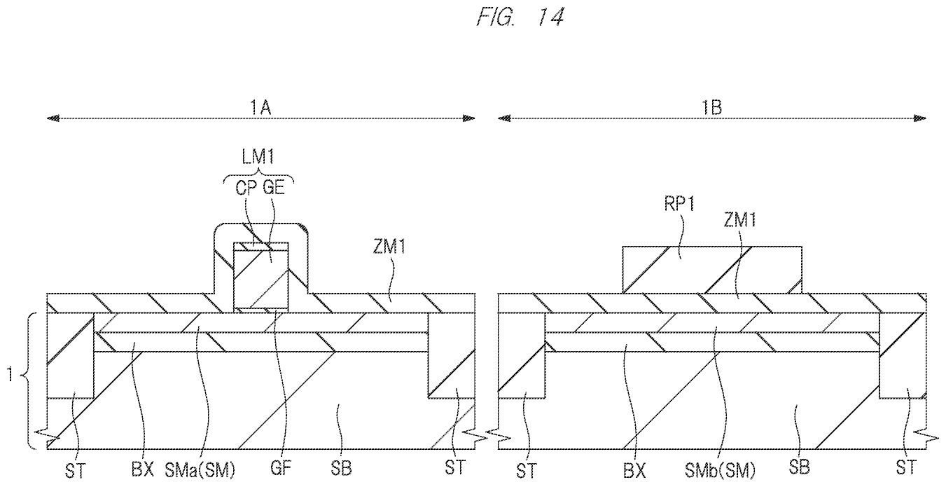

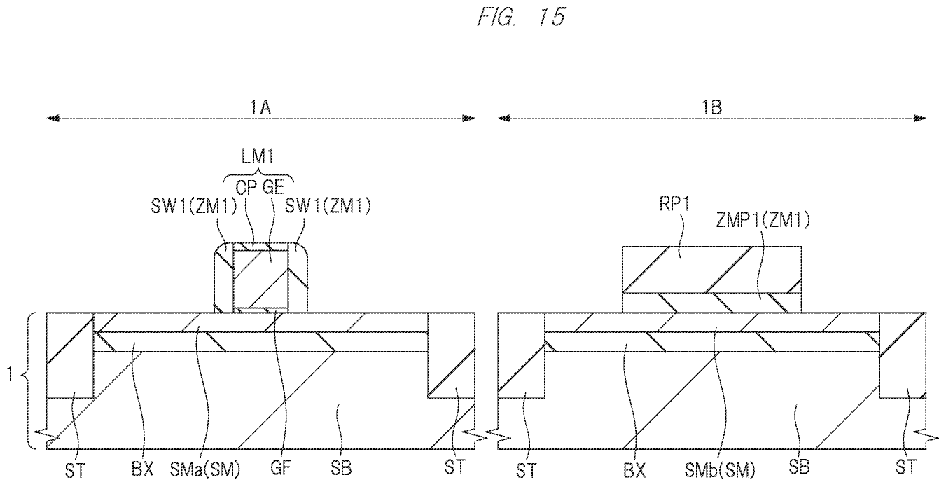

Next, as shown in FIG. 12, the element isolation regions ST are formed in the SOI substrate 1.

In order to form the element isolation region ST, for example, an element isolation trench ST1 is formed in the main surface of the SOI substrate 1 (semiconductor layer SM) by using a photolithographic technique, a dry etching technique, and the like so as to penetrate through the semiconductor layer SM and the insulating layer BX and for its bottom portion to reach the substrate SB. Since the bottom portion of the element isolation trench ST1 is located halfway in the thickness of the substrate SB, the substrate SB is exposed at the bottom portion of the element isolation trench ST1. Then, the isolation region ST can be formed by embedding an insulating film in the element isolation trench ST1 by using a film forming technique, a CMP technique, and the like.

In the SOI substrate 1, the element isolation region ST is formed, so that the semiconductor layer SM is divided into a plurality of sections (that is, active regions), and the semiconductor layer SM configuring the respective active regions becomes surrounded by the element isolation region ST. The semiconductor layer SM located in the MISFET formation region 1A is the semiconductor layer SMa and the semiconductor layer SM located in the resistance element formation region 1B is the semiconductor layer SMb. Each of the semiconductor layers SMa and SMb has a bottom portion contacting with the insulating layer BX and a side surface contacting with the element isolation region ST.

Next, as shown in FIG. 13, in the MISFET formation region 1A, the gate electrode GE is formed over the main surface of the SOI substrate 1, that is, over the main surface of the semiconductor layer SM (SMa) via the gate insulating film GF. An insulating film (cap insulating film) CP having the same planar shape as that of the gate electrode GE may be formed on the gate electrode GE. Incidentally, the thickness of the gate electrode GE in the present embodiment is, for example, 100 nm. Incidentally, the term “same” used herein means that two or more objects (here, “planar shapes”) to be compared are substantially the same. That is, it means that the two or more objects to be compared are the same in the design, but are not necessarily the same in the actual manufactured products due to the manufacturing variations.

A specific example of each forming step of the gate insulating film GF and the gate electrode GE will be described. First, an insulating film for the gate insulating film GF is formed on the main surface of the SOI substrate 1, that is, on the main surface of the semiconductor layer SM. Thereafter, a conductive film (for example, poly silicon film) for the gate electrode GE is formed on this insulating film, and an insulating film (insulating film to become the insulating film CP later) is formed on this conductive film. At this stage, a laminated film of the conductive film for the gate electrode GE and the insulating film thereon is formed in both the MISFET formation region 1A and the resistance element formation region 1B. Then, the laminated film of the conductive film for the gate electrode GE and the insulating film thereon is patterned by using a photolithographic technique and an etching technique, thereby being able to form the gate electrode GE made of the patterned conductive film. The gate electrode GE is formed in the MISFET formation region 1A, and the insulating film for the gate insulating film GF remains between the gate electrode GE and the semiconductor layer SM, and this becomes the gate insulating film GF. Moreover, the insulating film CP patterned so as to have the same planar shape as that of the gate electrode GE becomes formed on the gate electrode GE. In the resistance element formation region 1B, the entire laminated film of the conductive film for the gate electrode GE and the insulating film thereon is removed. In addition, a portion other than the portion covered with the gate electrode GE in the insulating film for the gate insulating film GF can be removed by performing dry etching performed in a patterning step of the conductive film for the gate electrode GE or by performing wet etching after the dry etching is performed. Consequently, in the SOI substrate 1, the gate insulating film GF and the gate electrode GE are formed in the MISFET formation region 1A, but become not formed in the resistance element formation region 1B.

Incidentally, in the following description, a stack of the gate insulating film GF formed in the MISFET formation region 1A, the gate electrode GE thereon, and the insulating film CP thereon will be referred to as a stack LM1.

Next, as shown in FIG. 14, an insulating film ZM1 made of a silicon oxide film or the like is formed on the main surface of the SOI substrate 1, that is, on the main surface of the semiconductor layer SM so as to cover the stack LM1 by using a CVD (chemical vapor deposition) method or the like. Then, a photoresist pattern RP1 is formed on the insulating film ZM1 by using a photolithographic technique. The photoresist pattern RP1 is formed in the resistance element formation region 1B, but not formed in the MISFET formation region 1A.

Next, the insulating film ZM1 is etched back by using an anisotropic etching technique. By this etch-back step, as shown in FIG. 15, the insulating film ZM1 remains as sidewall spacers (sidewall insulating films) SW1 on sidewalls of the stack LM1 in the MISFET formation region 1A, the insulating film ZM1 remains as an insulating film pattern (patterned insulating film) ZMP1 under the photoresist pattern RP1 in the resistance element formation region 1B, and the insulating film ZM1 other than them is removed. Thereafter, the photoresist pattern RP1 is removed by ashing or the like.

In this way, the sidewall spacers (sidewall insulating films) SW1 are formed on the sidewalls of the stack LM1 in the MISFET formation region 1A, and the insulation film pattern ZMP1 is formed on the semiconductor layer SM in the resistance element formation region 1B. In the resistance element formation region 1B, the semiconductor layer SM has a portion covered with the insulating film pattern ZMP1 and a portion not covered with the insulating film pattern ZMP1.

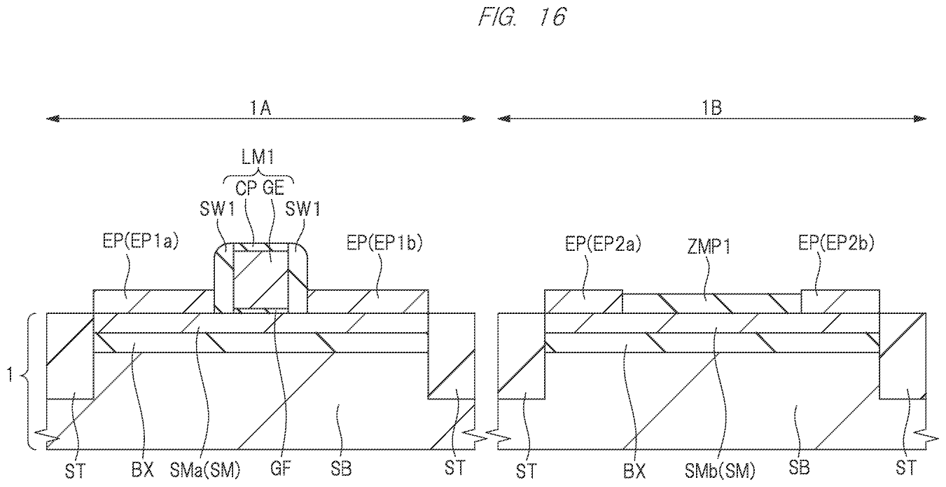

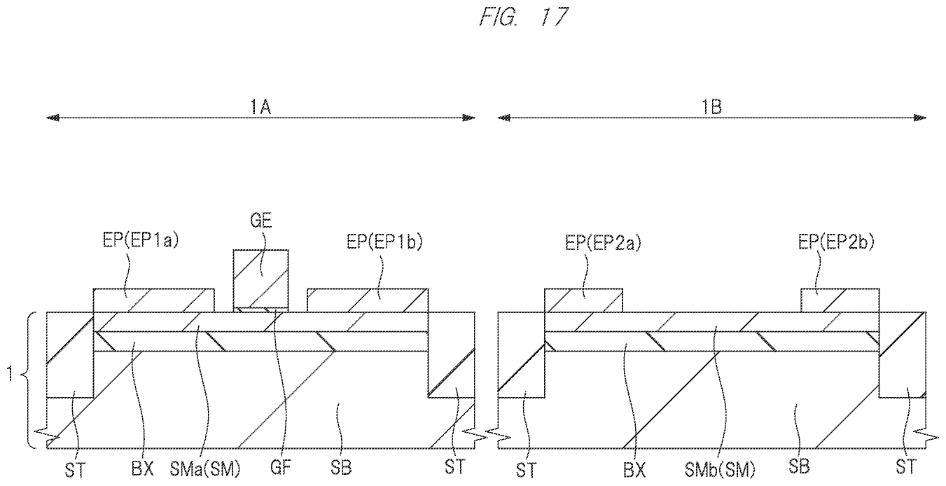

Next, as shown in FIG. 16, a semiconductor layer (epitaxial layer) EP is formed by an epitaxial growth method. The semiconductor layer EP is formed on the exposed surface of the semiconductor layer SM. In the MISFET formation region 1A, the semiconductor layer EP is formed on a portion of the semiconductor layer SMa not covered with the stack LM1 and the sidewall spacers SW1. That is, in the MISFET formation region 1A, the semiconductor layer EP is formed on regions of the semiconductor layer SMa located on both sides of a structure that is made of the stack LM1 and the sidewall spacers SW1 formed on the sidewalls thereof. In addition, in the resistance element formation region 1B, the semiconductor layer EP is formed on a portion of the semiconductor layer SMb which is not covered with the insulating film pattern ZMP1. The semiconductor layer EP is made of, for example, silicon (single crystal silicon). As described above, the semiconductor layer EP has semiconductor portions EP1a and EP1b formed in the MISFET formation region 1A and semiconductor portions EP2a and EP2b formed in the resistance element formation region 1B.

Next, as shown in FIG. 17, the sidewall spacer SW1 and the insulating film pattern ZMP1 are removed by etching. During this etching, the insulating film CP on the gate electrode GE can also be removed. Moreover, in this etching, it can be prevented or suppressed that the semiconductor layers EP, SM and the gate electrode GE are etched by the etching under the condition that the semiconductor layers EP, SM and the gate electrode GE are less likely to be etched than the sidewall spacers SW1 and the insulating film pattern ZMP1.

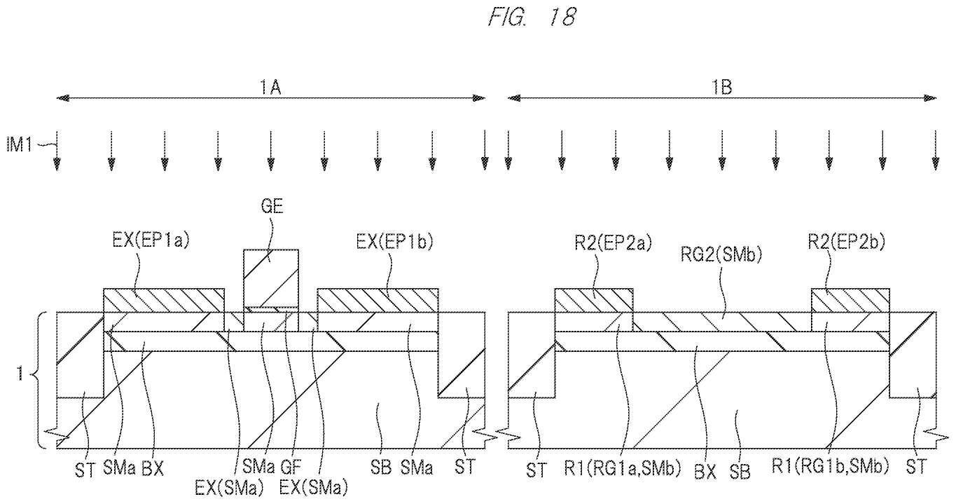

Next, as shown in FIG. 18, a p-type impurity such as boron (B) is ion-implanted into the semiconductor layers EP and SM in the MISFET formation region 1A and the resistance element formation region 1B. This ion implantation is hereinafter referred to as ion implantation IM1 and is schematically shown by arrows in FIG. 18. In the ion implantation IM1, implantation energy is adjusted so that the p-type impurity is introduced into the semiconductor layer EP, but the p-type impurity is not introduced into the semiconductor layer SM below the semiconductor layer EP. When the implantation energy of the ion implantation IM1 is high, the p-type impurity is also introduced into the semiconductor layer SM located below the semiconductor layer EP by the ion implantation IM1. However, by making the implantation energy of the ion implantation IM1 low to some extent, the ion implantation IM1 can be performed so that the p-type impurity is introduced into the semiconductor layer EP, but the p-type impurity is not introduced into the semiconductor layer SM located below the semiconductor layer EP.

By the ion implantation IM1, in the MISFET formation region 1A, the p-type impurity is implanted into the semiconductor layer EP (respective semiconductor portions EP1a and EP1b) and a region of the semiconductor layer SMa, which is not covered with the semiconductor layer EP (respective semiconductor portions EP1a and EP1b) and the gate electrode GE, thereby forming a p⁻-type semiconductor region EX.

Further, by the ion implantation IM1, in the resistance element formation region 1B, the p-type impurity is implanted into the semiconductor layer EP (respective semiconductor portions EP2a and EP2b) and a region of the semiconductor layer SMb, which is not covered with the semiconductor layer EP (respective semiconductor portions EP2a and EP2b). In the ion implantation IM1, in the resistance element formation region 1B, almost no p-type impurity is introduced into a region of the semiconductor layer SMb, which is covered with the semiconductor layer EP (respective semiconductor portions EP2a and EP2b).

In FIG. 18, in the semiconductor layer SMb and the semiconductor portions EP2a and EP2b in the resistance element formation region 1B, a region into which the p-type impurity is introduced by the ion implantation IM1 is shown as a medium concentration region R2, and a region into which the p-type impurity is not introduced by the ion implantation IM1 is shown as a low concentration region R1. A p-type impurity concentration of the middle concentration region R2 is higher than a p-type impurity concentration of the low concentration region R1. As can be seen from FIG. 18, at a stage of performing the ion implantation IM1, substantially the entirety of each of the semiconductor portions EP2a and EP2b in the resistance element formation region 1B becomes the medium concentration region R2, and substantially the entire region RG2 of the semiconductor layer SMb in the resistance element formation region 1B, which is not covered with the semiconductor layer EP (respective semiconductor portions EP2a and EP2b) has the same impurity concentration as the middle concentration region R2. Further, at the stage of performing the ion implantation IM1, substantially the entire regions RG1a and RG1b of the semiconductor layer SMb in the resistance element formation region 1B, which are covered with the semiconductor layer EP (respective semiconductor portions EP2a and EP2b) become the low concentration regions R1.

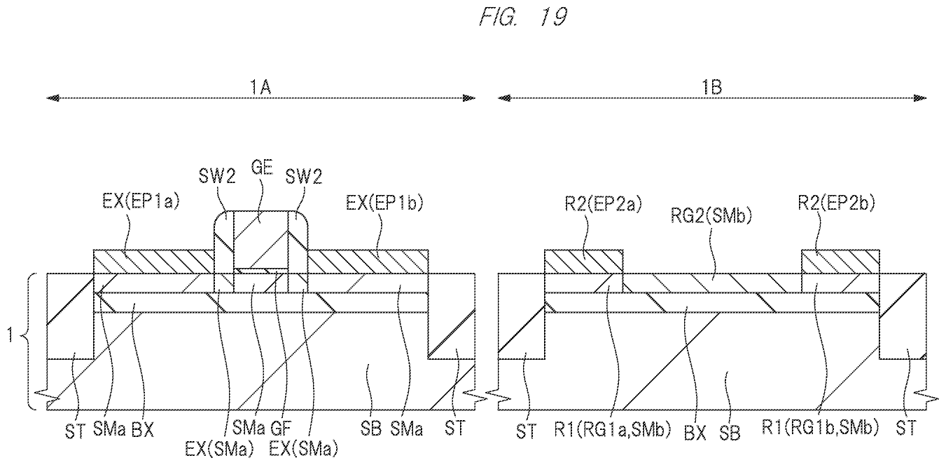

Next, as shown in FIG. 19, sidewall spacers SW2 are formed as sidewall insulating films on the sidewalls of the gate electrode GE. The sidewall spacers SW2 can be formed by, for example, forming a sidewall spacer SW2 formation insulating film on the main surface of the SOI substrate 1 so as to cover the gate electrode GE and the semiconductor layer EP and then etching back the insulating film by an anisotropically etching technique. The sidewall spacers SW2 are formed on the sidewalls of the gate electrode GE in the MISFET formation region 1A.

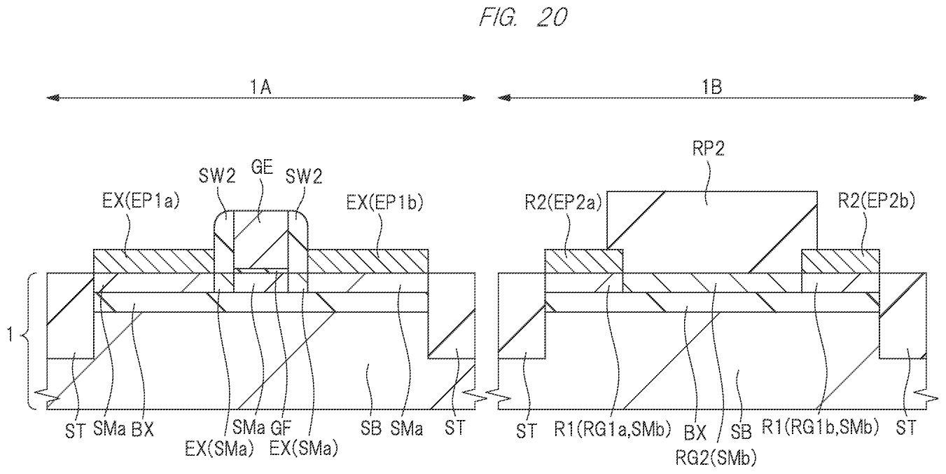

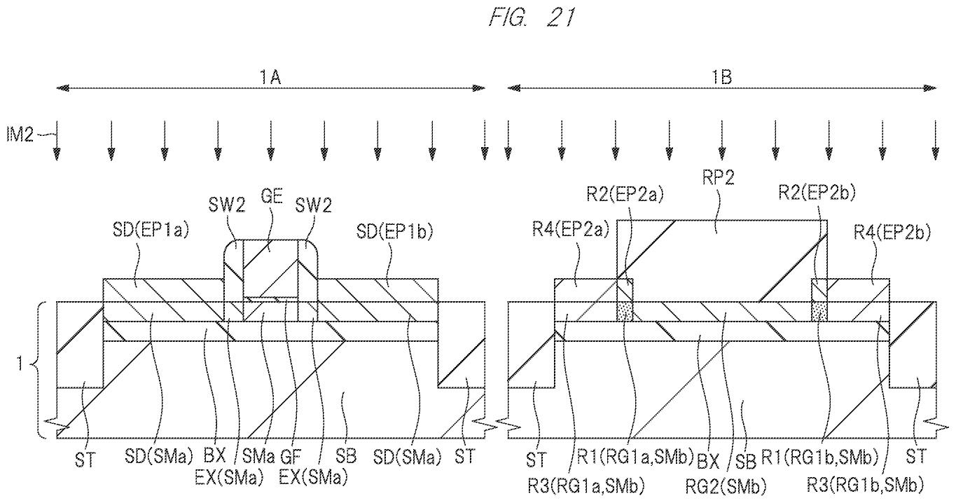

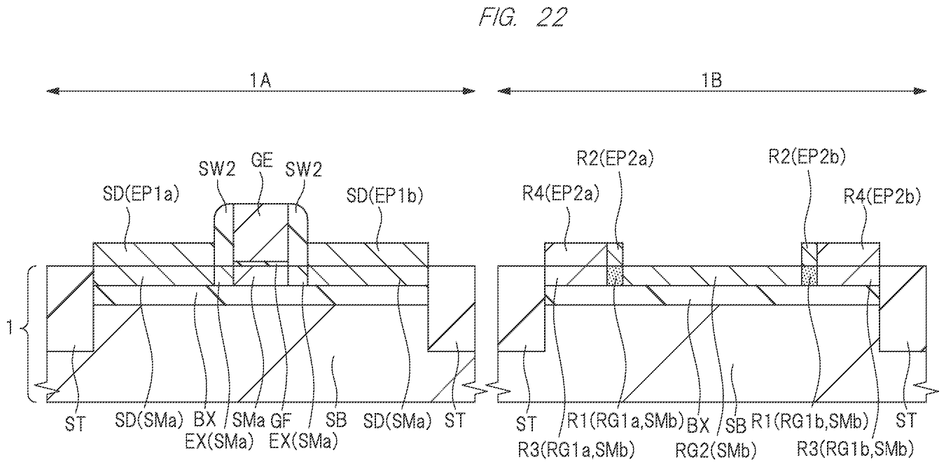

Next, as shown in FIG. 20, a photoresist pattern RP2 is formed over the semiconductor layer SMb and the semiconductor layer EP (semiconductor portions EP2a and EP2b) in the resistance element formation region 1B by using a photolithographic technique. In the resistance element formation region 1B, the photoresist pattern RP2 is formed so as to cover a region of the semiconductor layer SMb, which is not covered with the semiconductor layer EP (respective semiconductor portions EP2a and EP2b) and to cover one part of each of the semiconductor portions EP2a and EP2b.

In the semiconductor portion EP2a, a region near the end E1 is covered with the photoresist pattern RP2, but a region other than the region is exposed without being covered with the photoresist pattern RP2. Also, in the semiconductor portion EP2b, a region near the end E2 is covered with the photoresist pattern RP2, but a region other than the region is exposed without being covered with the photoresist pattern RP2. Here, the end E1 of the semiconductor portion EP2a and the end E2 of the semiconductor portion EP2b oppose each other in the X direction. In a plan view, the region RG2 of the semiconductor layer SMb, which is not covered with the semiconductor layer EP (respective semiconductor portions EP2a and EP2b), exists between the end E1 of the semiconductor portion EP2a and the end E2 of the semiconductor portion EP2b.

Next, as shown in FIG. 21, a p-type impurity such as boron (B) is ion-implanted into the semiconductor layers EP and SM in the MISFET formation region 1A and the resistance element formation region 1B. This ion implantation is hereinafter referred to as ion implantation IM2, and is schematically shown by arrows in FIG. 21. In the ion implantation IM2, the implantation energy is adjusted so that the p-type impurity is also introduced into the semiconductor layer SM under the semiconductor layer EP. Consequently, the implantation energy of the ion implantation IM2 is larger than the implantation energy of the ion implantation IM1 and, therefore, an implantation depth of the ion implantation IM2 is deeper than an implantation depth of the ion implantation IM1. Also, a dose amount of the ion implantation IM2 is larger than a dose amount of ion implantation IM1.

By the ion implantation IM, in the MISFET formation region 1A, the p-type impurity is implanted into the semiconductor layer EP (semiconductor portions EP1a and EP1b) and a region of the semiconductor layer SMa, which is not covered with the gate electrode GE and the sidewall spacer SW2, thereby forming the p⁺-type semiconductor region SD. The p-type impurity concentration of the p⁺-type semiconductor region SD is higher than the p-type impurity concentration of the p⁻-type semiconductor region EX. By the p⁻-type semiconductor region EX and the p⁺-type semiconductor region SD, a source or drain semiconductor region for the MISFET is formed.

Further, by the ion implantation IM2, in the resistance element formation region 1B, the p-type impurity is implanted into a region of the semiconductor layer EP (respective semiconductor portions EP2a and EP2b), which is not covered with the photoresist pattern RP2, and the semiconductor layer SMb located directly below the region. In the resistance element formation region 1B, the p-type impurity is not implanted by the ion implantation IM2 into a region of the semiconductor layer EP (respective semiconductor portions EP2a and EP2b), which is covered with the photoresist pattern RP2, and the semiconductor layer SMb located directly under the region. In the resistance element formation region 1B, the region RG2 of the semiconductor layer SMb, which is not covered with the semiconductor layer EP (respective semiconductor portions EP2a and EP2b), is covered with the photoresist pattern RP2, so that the p-type impurity is not implanted by the ion implantation IM2. After the ion implantation IM1, the photoresist pattern RP2 is removed as shown in FIG. 22.

FIGS. 21 and 22 show, in the semiconductor layer SMb and the semiconductor layer EP (respective semiconductor portions EP2a and EP2b) of the resistance element formation region 1B, the regions, into which the p-type impurity is introduced by the ion implantation IM2, as high concentration regions R3 and R4. The medium concentration region R2 is a region into which the p-type impurity is introduced by the ion implantation IM1, but the p-type impurity is not introduced by the ion-implantation IM2, and the low concentration region R1 is a region into which the p-type impurity is not introduced by none of the ion implantations IM1 and IM2. The p-type impurity concentration of each of the high concentration regions R3 and R4 is higher than the p-type impurity concentration of the medium concentration region R2, and the p-type impurity concentration of the medium concentration region R2 is higher than the p-type impurity concentration of the low concentration region R1. In addition, the p-type impurity concentration of each of the high concentration regions R3 and R4 is substantially the same as the p-type impurity concentration of the p⁺-type semiconductor region SD, and the p-type impurity concentration of the medium concentration region R2 is substantially the same as the p-type impurity concentration of the p⁻-type semiconductor region EX.

As can be seen from FIG. 22, at the stage of performing the ion implantation IM2, in the semiconductor portion EP2a in the resistance element formation region 1B, the region near the end E1 becomes the medium concentration region R2, and the region other than the region near the end E1 becomes the high concentration region R4. Further, in the semiconductor portion EP2b in the resistance element formation region 1B, the region near the end E2 becomes the middle concentration region R2, and the region other than the region near the end E2 becomes the high concentration region R4. In addition, substantially the entire region RG2 (the region not covered with the semiconductor layer EP) of the semiconductor layer SMb in the resistance element formation region 1B has the same impurity concentration as that of the middle concentration region R2. Moreover, in the region RG1a (the region covered with the semiconductor portion EP2a) of the semiconductor layer SMb in the resistance element formation region 1B, the region next to the region RG2 becomes the low concentration region R1, and the region other than the region becomes the high concentration region R3. In addition, in the above-mentioned region RG1b (the region covered with the semiconductor portion EP2b) of the semiconductor layer SMb in the resistance element formation region 1B, the region next to the region RG2 is the low concentration region R1, and the region other than the region becomes the high concentration region R3. The high concentration region R4 of the semiconductor portion EP2a and the high concentration region R3 in the region RG1a of the semiconductor layer SMb overlap vertically, and the middle concentration region R2 of the semiconductor portion EP2a and the low concentration region R1 in the region RG1a of the semiconductor layer SMb overlap vertically. Moreover, the high concentration region R4 of the semiconductor portion EP2b and the high concentration region R3 in the region RG1b of the semiconductor layer SMb overlap vertically, and the middle concentration region R2 of the semiconductor portion EP2b and the low concentration region R1 in the region RG1b of the semiconductor layer SMb overlap vertically.

Next, if necessary, activation annealing, which is a heat treatment for activating the impurities introduced so far, is performed.

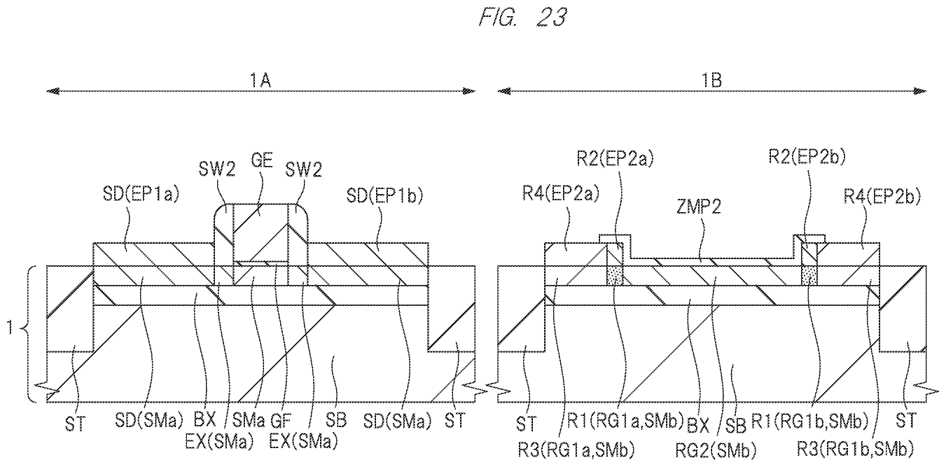

Next, an insulating film (for example, a silicon oxide film) is formed over the main surface of the SOI substrate 1 so as to cover the gate electrode GE, the sidewall spacers SW2 and the p⁺-type semiconductor region SD in the MISFET formation region 1A and to cover the semiconductor layers EP and SMb in the resistance element formation region 1B. Then, the insulating film is patterned by using a photolithographic technique and an etching technique to form the insulating film pattern ZMP2 made of the patterned insulating film, as shown in FIG. 23.

In the resistance element formation region 1B, the insulating film pattern ZMP2 is formed over and on the semiconductor layers EP and SMb. In the resistance element formation region 1B, the region RG2 of the semiconductor layer SMb, which is not covered with the semiconductor layer EP, is covered with the insulating film pattern ZMP2. In addition, in the resistance element formation region 1B, the insulating film pattern ZMP2 runs on a part of each of the semiconductor portions EP2a and EP2b. The middle concentration region R2 of the semiconductor portion EP2a is covered with the insulating film pattern ZMP2, but at least a part of the high concentration region R4 of the semiconductor portion EP2a is exposed without being covered with the insulating film pattern ZMP2. Further, the middle concentration region R2 of the semiconductor portion EP2b is covered with the insulating film pattern ZMP2, but at least a part of the high concentration region R4 of the semiconductor portion EP2b is exposed without being covered with the insulating film pattern ZMP2.

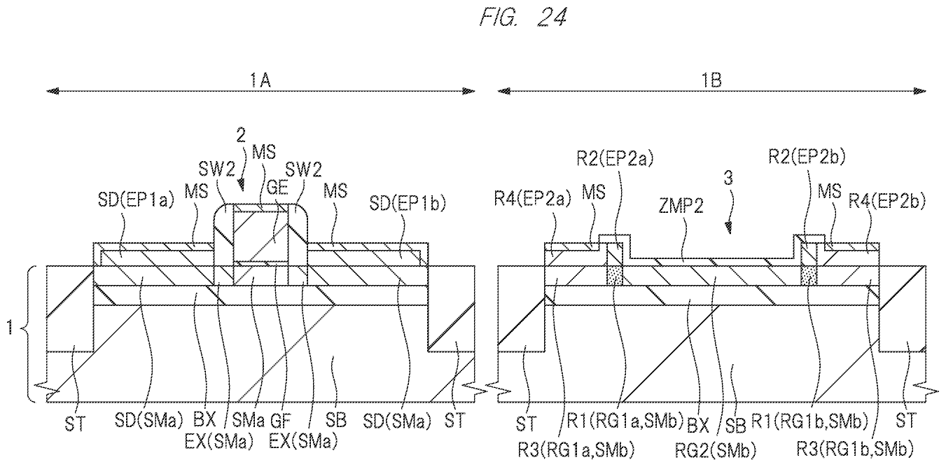

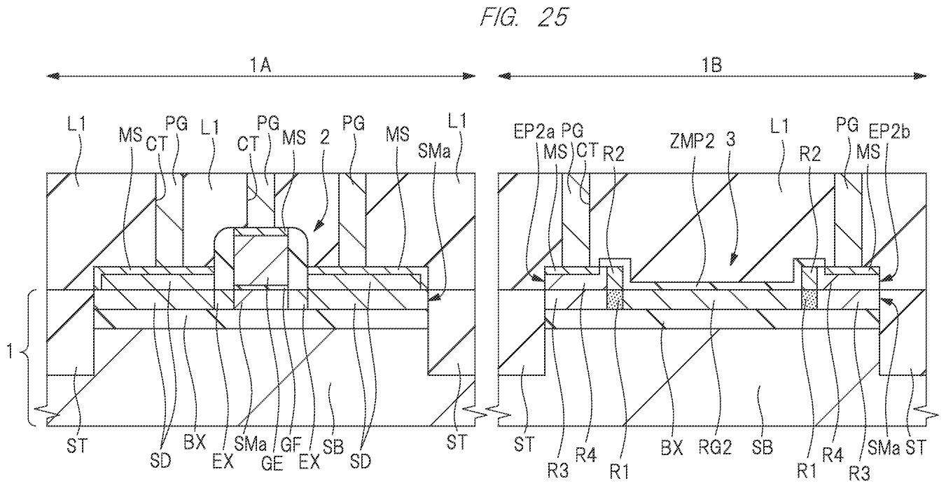

Next, as shown in FIG. 24, the metal silicide layer (metal compound layer) MS is formed by a Salicide (Self Aligned Silicide) technique. In the MISFET formation region 1A, the metal silicide layer MS is formed on the surface (upper layer portion) of the p⁺-type semiconductor region SD, that is, the surface (upper layer portion) of the semiconductor layer EP and the surface (upper layer portion) of the gate electrode GE. In addition, in the resistance element formation region 1B, the metal silicide layer MS is formed in a part of the surface of the semiconductor layer EP (semiconductor portions EP2a, EP2a), which is not covered with the insulating film pattern ZMP2.

In the resistance element formation region 1B, the metal silicide layer MS is formed in a part of the surface of the semiconductor layer EP (semiconductor portions EP2a, EP2a), which is not covered with the insulating film pattern ZMP2, but the metal silicide layer MS is not formed in the part that is covered with the insulating film pattern ZMP2. Therefore, the metal silicide layer MS is formed on the surface of the high concentration region R4 of the semiconductor portion EP2a, and the metal silicide layer MS is formed on the surface of the high concentration region R4 of the semiconductor portion EP2b. The metal silicide layer MS is not formed on the surface of the medium concentration region R2 of the semiconductor portion EP2a and the surface of the medium concentration region R2 of the semiconductor portion EP2b. Further, in the resistance element formation region 1B, the region RG2 of the semiconductor layer SMb, which is not covered with the semiconductor layer EP, is covered with the insulating film pattern ZMP2. Therefore, in the resistance element formation region 1B, the metal silicide layer MS is not formed on the surface of the semiconductor layer SMb. The insulating film pattern ZMP2 can function as a silicide block layer that prevents formation of the metal silicide layer MS.

Thus, the MISFET 2 is formed in the MISFET formation region 1A, and the resistance element 3 is formed in the resistance element formation region 1B.

Next, as shown in FIG. 25, the insulating film (Interlayer insulating film) L1 is formed as an interlayer insulating film on the main surface of the SOI substrate 1 so as to cover the gate electrode GE, the semiconductor layers EP and SM, the sidewall spacers SW2, and the metal silicide layer MS. After the formation of the insulating film L1, if necessary, flatness of the upper surface of the insulating film L1 can also be enhanced by polishing or the like the upper surface of the insulating film L1 by a CMP method.

Next, the contact hole (through hole, hole) CT is formed in the insulating film L1 by using a photolithographic technique and an etching technique. The contact hole CT is formed so as to penetrate through the insulating film L1. In the MISFET formation region 1A, the contact hole CT is formed over the gate electrode GE and over the p⁺-type semiconductor region SD. Further, in the resistance element formation region 1B, the contact hole CT is formed over the semiconductor layer EP (semiconductor portions EP2a, EP2a). In a contact hole CT formation step, etching is preferably performed under the condition that the metal silicide layer MS and the semiconductor layers EP and SM are less likely to be etched than the insulating film L1.

Next, as shown in FIG. 25, the conductive plug PG made of tungsten (W) or the like is formed as a conductive portion for connection in the contact hole CT.

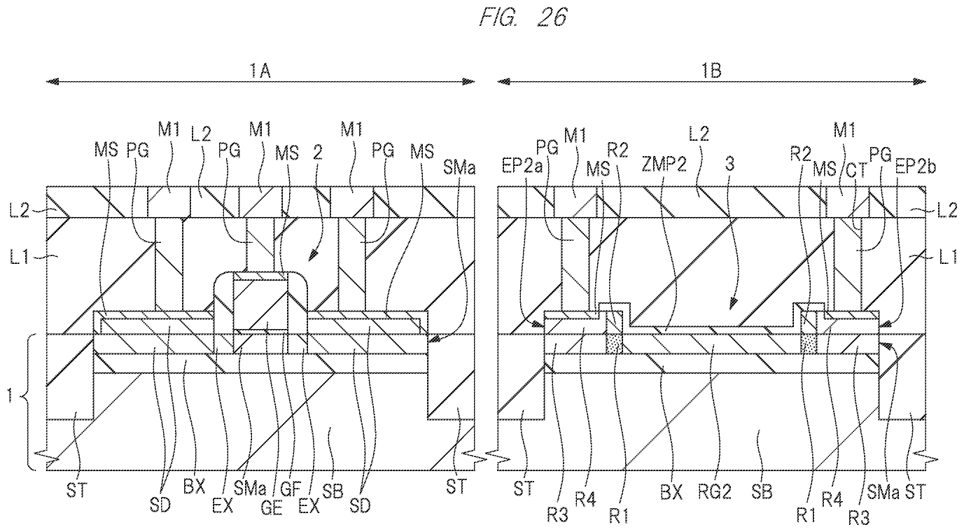

Next, as shown in FIG. 26, the insulating film L2 for wiring formation is formed on the insulating film L1 in which the plugs PG are embedded.

Next, as shown in FIG. 26, the wiring M1, which is a first layer wiring, is formed by using a single damascene method. That is, after forming the wiring trench in the insulating film L2, the wiring M1 is formed in the wiring trench.

Thereafter, second and subsequent layer wirings are formed by using a dual damascene method or the like, but illustration and description thereof will be omitted here. Also, the wiring M1 and the upper lay wiring higher than it are not limited to the damascene wirings, and may be formed by patterning the conductive film for wiring, for example, by a tungsten wiring, an aluminum wiring, or the like.

As described above, the semiconductor device of the present embodiment is manufactured.

### <Regarding Main Features and Effects>

In the present embodiment, the resistance element 3 is formed by the semiconductor layer SM forming the SOI substrate and the epitaxial semiconductor layer (semiconductor layer EP) formed on the semiconductor layer SM.

Specifically, as shown in FIGS. 2 to 5, the resistance element 3 is formed by the semiconductor layer SMb, which is the semiconductor layer SM located in the resistance element formation region 1B, and the semiconductor layer EP (epitaxial semiconductor layer) formed on the semiconductor layer SMb. The semiconductor layer EP has the two semiconductor portions EP2a and EP2b formed separately from each other on the semiconductor layer SMb. The semiconductor layer SMb includes: the region RG1a (first connection portion) on which the semiconductor portion EP2a is formed; the region RG1b (second connection portion) on which the semiconductor portion EP2b is formed; and the region RG2 (element portion, center portion) that is located between the region RG1a and the region RG1b and on which the semiconductor layer EP is not formed.

In the present embodiment, the semiconductor layer SMb configuring the resistance element 3 has the region RG2 (element portion, center portion), on which the semiconductor layer EP is not formed, and the resistance value of the resistance element 3 can be increased by the region RG2. That is, the semiconductor layer EP is not formed on the semiconductor layer SMb located in the region RG2, and the thickness of the resistance element 3 in the region RG2 is thinner than the thickness of the resistance element 3 in each of the regions RG1a and RG1b. This makes it possible to earn the resistance value of the resistance element 3 by the region RG2. Specifically, the thickness T1 (see FIG. 2) of the semiconductor layer SMb is thinner than the thickness of the gate electrode GE, preferably 30 nm or less (T1≤30 nm). By using the semiconductor layer SMb, which is located in the region RG2 and has a thin (small) thickness T1, as a current path of the resistance element 3, the resistance value of the resistance element 3 can be earned and, as a result, the resistance value of the resistance element 3 can be increased. Further, the region RG2 of the semiconductor layer SMb having the thin thickness T1 earns the resistance value of the resistance element 3, so that the length of the resistance element 3 required to secure the required resistance value (length along the direction in which the current flows) can be suppressed. Consequently, since the area required for arranging the resistance element 3 can be suppressed in the semiconductor device, this is advantageous for the miniaturization (reduction in area) of the semiconductor device.

Also, the semiconductor layer SM of the SOI substrate 1 is used to form the MISFET 2 and the resistance element 3, and the channel region of the MISFET 2 is formed in the semiconductor layer SMa located directly under the gate electrode GE. Therefore, the thickness T1 of the region RG2 of the semiconductor layer SMb is approximately the same as the thickness of the semiconductor layer SMa located directly under the gate electrode GE of the MISFET. The thickness of each of the semiconductor layer SMa and the semiconductor layer SMb is preferably 30 nm or less, more preferably 3 nm to 30 nm.

Here, unlike the present embodiment, it is assumed that the semiconductor layer EP (semiconductor portions EP2a and EP2b) is not formed on the semiconductor layer SMb. In this case, the plugs PG2a and PG2b are connected to the semiconductor layer SMb instead of the semiconductor portions EP2a and EP2b. However, in this case, since the thickness of the semiconductor layer SMb is thin in forming the contact holes CT, there is a concern that the contact holes CT2a and CT2b may pierce (penetrate through) the semiconductor layer SMb, which is undesirable.

In contrast, in the present embodiment, the semiconductor portion EP2a is formed on the region RG1a of the semiconductor layer SMb, the semiconductor portion EP2b is formed on the region RG1b of the semiconductor layer SMb, the plug PG2a is arranged over the semiconductor portion EP2a and is electrically connected to the semiconductor portion EP2a, and the plug PG2b is arranged over the semiconductor portion EP2b and is electrically connected to the semiconductor portion EP2b. Therefore, in forming the contact holes CT, it is possible to adequately prevent the contact holes CT2a and CT2b from piercing (penetrating through) the semiconductor layers EP and SMb. This makes it possible to improve the reliability of the semiconductor device. Moreover, the manufacturing yield of the semiconductor device can be improved.

Further, in the present embodiment, as shown in FIGS. 2 to 5, the semiconductor portions EP2a and EP2b are formed on the semiconductor layer SMb, and the metal silicide layer MS is formed on the surface (upper layer portion) of each of the semiconductor portions EP2a and EP2b. Therefore, in the resistance element formation region 1B, the thickness of the semiconductor region (here, the semiconductor layer EP and the semiconductor layer SMb) used for forming the metal silicide layer MS can be thickened by the thickness corresponding to presence of the semiconductor portions EP2a and EP2b, so that the metal silicide layer MS can be adequately formed.

The thickness of the semiconductor layer EP (respective semiconductor portions EP2a and EP2b) formed on the semiconductor layer SMb can be, for example, about 20 nm to 60 nm.

In the present embodiment, the resistance element 3 is formed of the semiconductor layer SMb and the semiconductor layer EP (semiconductor portions EP2a and EP2b). One of the main features of the present embodiment is that resistance of the resistance element 3 is further increased by devising the impurity concentrations in the semiconductor layer SMb and the semiconductor layer EP (respective semiconductor portions EP2a and EP2b).

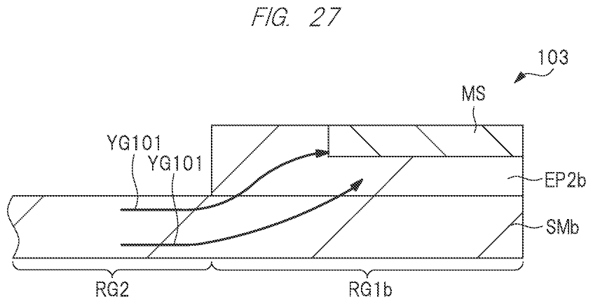

That is, in the present embodiment, each of the regions RG1a and RG1b (first connection portion and second connection portion) of the semiconductor layer SMb is located next to the region RG2 (element portion, center portion) of the semiconductor layer SMb, and has the p-type low concentration region R1 (first low concentration region) having an impurity concentration lower than that of the region RG2 (element portion, center portion) of the semiconductor layer SMb. In addition, each of the semiconductor portions EP2a and EP2b has the p-type middle concentration region R2 (first middle concentration region), which is located on the low concentration region R1 and is has an impurity concentration higher than that of the low concentration region R1. Consequently, the resistance of the resistance element 3 can be increased. This will be described below with reference to FIG. 27 and FIG. 10 mentioned above.

Here, it is assumed that the impurity concentrations in the semiconductor layer SMb and the semiconductor portions EP2a and EP2b configuring the resistance element 3 are uniform, and this case is hereinafter referred to as a study example. Also, the resistance element 3 in the study example is referred to as a resistance element 103. FIG. 27 is a partially enlarged cross-sectional view of the resistance element 103 of the study example, and shows a cross-sectional view corresponding to FIG. 10 mentioned above.

The resistance element 103 of the study example differs from the resistance element 3 of the present embodiment in that the impurity concentrations in the semiconductor layer SMb and the semiconductor portions EP2a and EP2b are uniform in the resistance element 103 of the study example.

When a current flows in the resistance element 103 of the study example, the current mainly flows in paths YG101 schematically shown in FIG. 27. Incidentally, here, a case where a potential of the above-mentioned plug PG2a is higher than a potential of the plug PG2b is described. In a case of the resistance element 103 of the study example, since the impurity concentration is substantially uniform throughout the entire resistance element 103, the current passing through the region RG2 of the semiconductor layer SMb smoothly flows toward the region RG1b of the semiconductor layer SMb and the semiconductor portion EP2b thereon, reaches the metal silicide layer MS formed on the surface of the semiconductor portion EP2b, and further flows from the metal silicide layer MS to the plug PG2b thereon.

In contrast, when the current flows in the resistance element 3 of the present embodiment, the current mainly flows in the paths YG1 schematically shown in FIG. 10. Incidentally, here too, the case where the potential of the plug PG2b is higher than the potential of the plug PG2a is described.

In the case of the resistance element 3 of the present embodiment, the region RG1b of the semiconductor layer SMb has the low concentration region R1 next to the region RG2 (element portion, center portion) of the semiconductor layer SMb and the semiconductor portion EP2b has the middle concentration region R2 located on the low concentration region R1. The impurity concentration of the low concentration region R1 in the region RG1b of the semiconductor layer SMb is lower than the impurity concentration of the region RG2 (element portion, center portion) of the semiconductor layer SMb, and the impurity concentration of the medium concentration region R2 in the region RG1b of the semiconductor layer SMb is higher than the impurity concentration of the low concentration region R1. Consequently, the current that has passed through the region RG2 of the semiconductor layer SMb mainly flows toward the middle concentration region R2 of the semiconductor portion EP2b while avoiding the low concentration region R1 in the region RG1b of the semiconductor layer SMb, and passes through the semiconductor portion EP2b to reach the metal silicide layer MS formed on the surface of the semiconductor portion EP2b, and further flows from the metal silicide layer MS to the plug PG2b thereon.

In the low concentration region R1 in the region RG1b next to the region RG2 of the semiconductor layer SMb, it is difficult for the current to flow, so that the main paths of the current converge at the region R5 shown in FIG. 10. This means that a cross-section area of the current path (area of a cross-section substantially perpendicular to a current direction) becomes smaller at the region R5 shown in FIG. 10. As a result, the resistance element 3 of the present embodiment can earn the resistance value of the resistance element 3 in the region R5 shown in FIG. 10. Therefore, the resistance value of the resistance element 3 of the present embodiment is larger than that of the resistance element 103 of the study example. Incidentally, the region R5 corresponds to a near region of a location where the upper surface of the semiconductor layer SMb and the end E2 of the semiconductor portion EP2b contact with each other.

In addition, the current does not always flow in the low concentration region R1 in the region RG1b of the semiconductor layer SMb, and may also flow in the low concentration region R1 with a lower current density than that of the main path. Even in that case, the current flowing in the low concentration region R1 in the region RG1b of the semiconductor layer SMb becomes small by making the impurity concentration of the low concentration region R1 in the region RG1b lower than that of the region RG2 of the semiconductor layer SMb.

A similar phenomenon occurs also in the region RG1a and the semiconductor portion EP2a of the semiconductor layer SMb. However, the current direction is opposite, and the current that has passed through the semiconductor portion EP2a from the metal silicide layer MS formed on the surface of the semiconductor portion EP2a mainly flows from the medium concentration region R2 of the semiconductor portion EP2a toward the region RG2 (element portion) of the semiconductor layer SMb while avoiding the low concentration region R1 in the region RG1a of the semiconductor layer SMb. As a result, the resistance of the resistance element 3 increases.

In addition, although the case where the potential of the plug PG2a is higher than the potential of the plug PG2b has been described here, the direction of the current flowing in the resistance element 3 is reversed also when the potential of the plug PG2b is higher than the potential of the plug PG2a. However, the same phenomenon as in the case where the potential of the plug PG2a is higher than the potential of the plug PG2b can occur.

In this way, in the present embodiment, by devising the impurity concentrations in the semiconductor layer SMb and the semiconductor layer EP (respective semiconductor portions EP2a and EP2b), the resistance of the resistance element 3 can be increased without changing dimensions of the resistance element 3. Consequently, the resistance value of the resistance element 3 can be increased without increasing the area required for arranging the resistance element 3 in the semiconductor device, therefore, without inviting the increase in the area of the semiconductor device. Therefore, it is advantageous for the miniaturization (reduction in area) of the semiconductor device.

Further, in the present embodiment, each of the regions RG1a and RG1b of the semiconductor layer SMb further has the high concentration region R3 (first high concentration region R3), which is next to the low concentration region R1 and has an impurity concentration higher than that of the middle concentration region R2. Furthermore, each of the semiconductor portions EP2a and EP2b further has the high concentration region R4 (second high concentration region), which is located on the high concentration region R3 and has an impurity concentration higher than that of the middle concentration region R2. The low concentration region R1 in the region RG1a of the semiconductor layer SMb is interposed between the region RG2 of the semiconductor layer SMb and the high concentration region R3 in the region RG1a of the semiconductor layer SMb. In addition, the low concentration region R1 in the region RG1b of the semiconductor layer SMb is interposed between the region RG2 of the semiconductor layer SMb and the high concentration region R3 in the region RG1b of the semiconductor layer SMb. Then, the metal silicide layer MS is formed on each of the surface of the high concentration region R4 of the semiconductor portion EP2a and the surface of the high concentration region R4 of the semiconductor portion EP2b.

Variations (fluctuations) in a contact resistance between the plugs PG2a and PG2b and the semiconductor portions EP2a and EP2b can become a factor in variations (fluctuations) in the resistance value of the resistance element 3. In the present embodiment, the high concentration region R4 is provided in each of the semiconductor portions EP2a and EP2b, and the metal silicide layer MS is formed on the surface of the high concentration region R4. This makes it possible to reduce the contact resistance between the plugs PG2a and PG2b and the semiconductor portions EP2a and EP2b and to suppress the variations (fluctuations) in the contact resistance between the plugs PG2a and PG2b and the semiconductor portions EP2a and EP2b. As a result, it is possible to suppress or prevent the variations (fluctuations) in the resistance value of the resistance element 3 and to suppress or prevent deviations from design values in the resistance value of the resistance element 3. This makes it possible to improve the performance of the semiconductor device having the resistance element 3.

The semiconductor portions EP2a and EP2b configuring the resistance element 3 can be formed in the same process as that of the semiconductor layers EP (respective semiconductor portions EP1a and EP1b) configuring the source/drain regions (p⁺-type semiconductor regions SD) of the MISFET 2 by an epitaxial growth method. Further, the medium concentration regions R3 of the respective semiconductor portions EP2a and EP2b configuring the resistance element 3 can be formed by the ion implantation process for forming the p⁻-type semiconductor region EX for the MISFET 2. In addition, the high concentration regions R4 of the semiconductor portions EP2a and EP2b configuring the resistance element 3 and the high concentration region R3 of the semiconductor layer SMb can be formed by the ion implantation process for forming the p⁺-type semiconductor region SD for the MISFET 2. Consequently, the number of manufacturing processes of the semiconductor device can be suppressed, and the manufacturing cost of the semiconductor device can be suppressed.

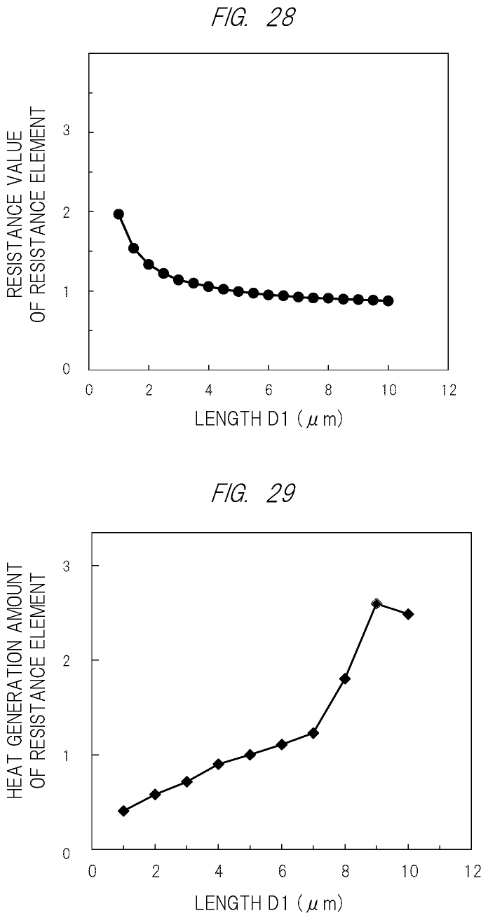

FIG. 28 is a graph showing a correlation between a sheet resistance of the resistance element 3 and a length D1 of the region RG2 of the semiconductor layer SMb. A vertical axis of the rough graph in FIG. 28 corresponds to the sheet resistance of the resistance element 3. Further, a horizontal axis of FIG. 28 corresponds to the length D1 of the region RG2 of the semiconductor layer SMb configuring the resistance element 3. However, the sheet resistance on the vertical axis of the graph in FIG. 28 is standardized by the sheet resistance when D1=5 μm. The length D1 is substantially parallel to the main surface of the SOI substrate 1 and along the current direction, and corresponds to the length (dimension) in the X direction in FIG. 1. In addition, the length D1 also corresponds to an interval between the semiconductor portion EP2a and the semiconductor portion EP2b.

As can be seen from the graph of FIG. 28, the sheet resistance of the resistance element 3 increases as the length D1 of the region RG2 of the semiconductor layer SMb configuring the resistance element 3 is shortened. This reason is conceivable as follows: regarding an occupation ratio of the resistance to the total resistance of the resistance element 3, the increase in the resistance due to it having been difficult for the current to flow in the low concentration regions R1 of the regions RG1a and RG1b of the semiconductor layer SMb as described above becomes large as the above-mentioned length D1 becomes short. Therefore, the present embodiment has a great effect when the length D1 is short. The above-mentioned length D1 is preferably 5 μm or less (that is, D1≤5 μm), more preferably 3 μm or less (that is, D1≤3 μm), and even more preferably 2 μm or less (that is, D1≤2 μm).

FIG. 29 is a graph showing a correlation between a heat generation amount of the resistance element 3 and the above-mentioned length D1. The vertical axis of the graph in FIG. 29 corresponds to the heat generation amount of the resistance element 3. In addition, the horizontal axis of the graph in FIG. 29 corresponds to the length D1 of the region RG2 of the semiconductor layer SMb configuring the resistance element 3. However, the heat generation amount of the vertical axis of the graph in FIG. 29 is normalized by the heat generation amount when D1=5 μm.

In FIG. 29, it can be seen that a slope of the graph increases when the above-mentioned length D1 is 7 μm or more. Consequently, the above-mentioned length D1 is preferably 7 μm or less (that is, D1≤7 μm).

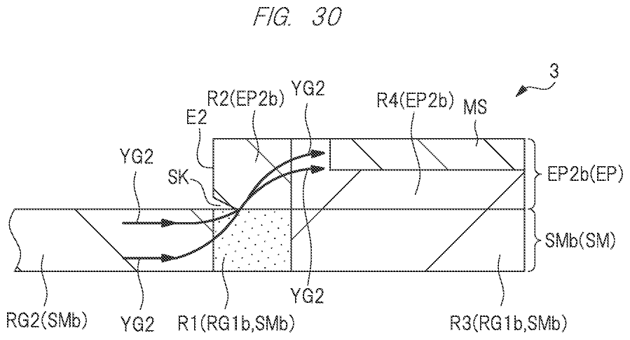

Next, a modification example of the resistance element 3 of the present embodiment will be described with reference to FIG. 30. FIG. 30 is a cross-sectional view showing a modification example of the resistance element 3 of the present embodiment, and shows a cross-sectional view corresponding to FIG. 10 mentioned above.

In a case of FIG. 30 (modification example), a gap SK is formed between the semiconductor portion EP2b and the underlying semiconductor layer SMb in the vicinity of the end E2 of the semiconductor portion EP2b. Further, in the vicinity of the end E1 of the semiconductor portion EP2a, a gap SK is formed between the semiconductor portion EP2a and the underlying semiconductor layer SMb, but this structure corresponds to a structure in which the reference numeral EP2b is replaced with the reference numeral EP2a, the reference numeral E2 is replaced with the reference numeral E1, and the reference numeral RG1b is replaced with the reference numeral RG1a.

The gap SK is a portion in which the semiconductor layer EP (respective semiconductor portions EP2a and EP2b) is present above the semiconductor layer SMb and the lower surface of the semiconductor layer EP (respective semiconductor portions EP2a and EP2b) and the upper surface of the semiconductor layer SMb are spaced apart from each other. Incidentally, the gap SK is filled with the insulating film pattern ZMP2.

In the case of FIG. 10 mentioned above, when the current flows in the resistance element 3, the current mainly flows in paths YG2 schematically shown in FIG. 10. That is, the current that has passed through the region RG2 of the semiconductor layer SMb flows toward the middle concentration region R2 of the semiconductor portion EP2b while avoiding the low concentration region R1 in the region RG1b of the semiconductor layer SMb, and passes through the semiconductor portion EP2b to reach the metal silicide layer MS formed on the surface of the semiconductor portion EP2b.

Meanwhile, in the case of FIG. 30 (modification example), the current cannot cross the gap SK. Consequently, in the case of FIG. 30 (modification example), the current mainly flows in the paths YG2 schematically shown in FIG. 30. That is, the current that has passed through the region RG2 of the semiconductor layer SMb avoids the gap SK, once enters the low concentration region R1 in the region RG1b of the semiconductor layer SMb, then flows toward the middle concentration region of the semiconductor portion EP2b above the low concentration region R1, and passes through the semiconductor portion EP2b to reach the metal silicide layer MS formed on the surface of the semiconductor portion EP2b. In the case of FIG. 30 (modification example), since the current path passes through a part of the low concentration region R1 by providing the gap SK, the resistance value of the resistance element 3 can be further increased than that of the case in which the gap SK is absent. Consequently, in the case of FIG. 30 (modification example), the resistance value of the resistance element 3 can be further increased without changing the dimensions of the resistance element 3. Thus, when the modification example of FIG. 30 is applied, the resistance value of the resistance element 3 can be further increased without increasing the area required for arranging the resistance element 3 in the semiconductor device, therefore, without inviting the increase in the area of the semiconductor device, so that it is more advantageous for the miniaturization (reduction in area) of the semiconductor device.

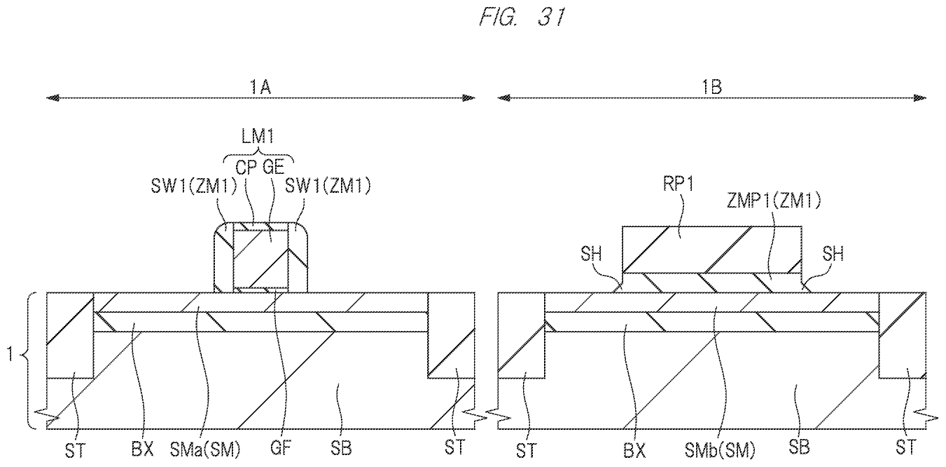

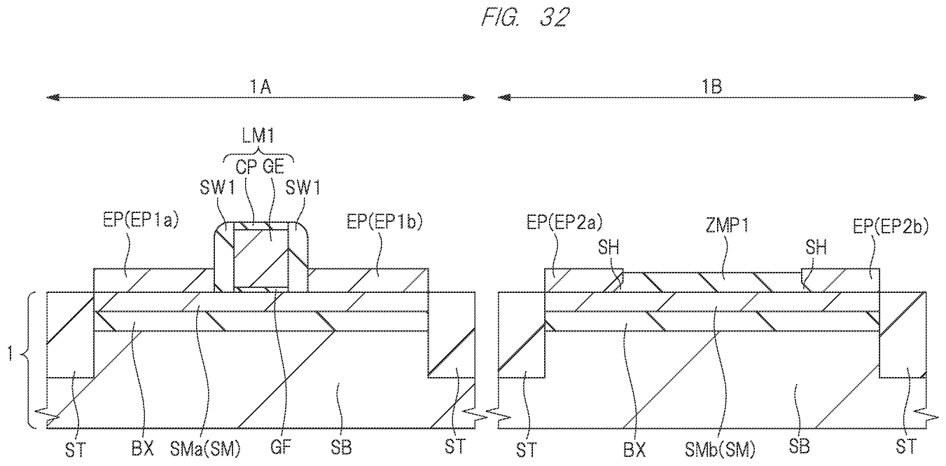

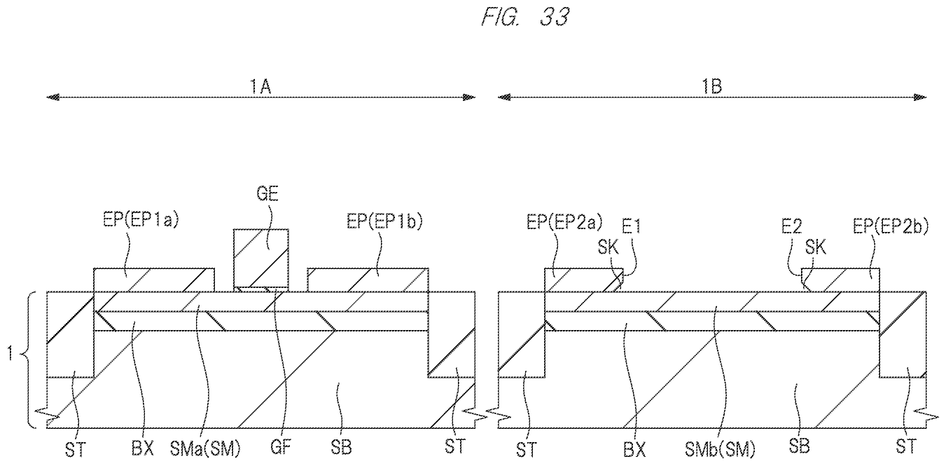

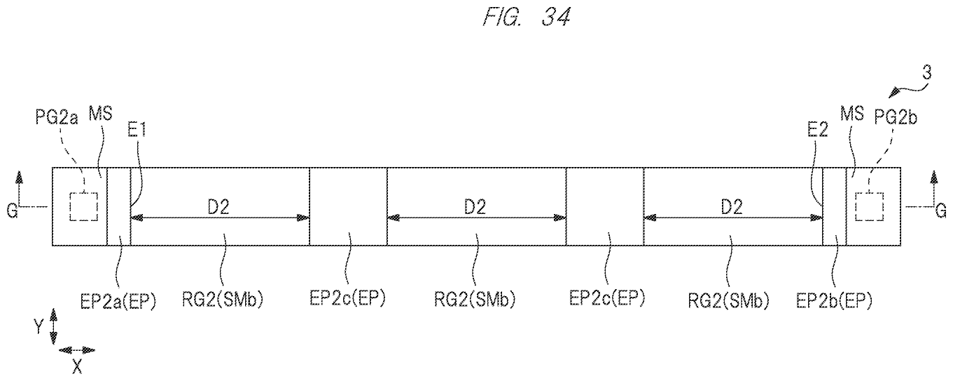

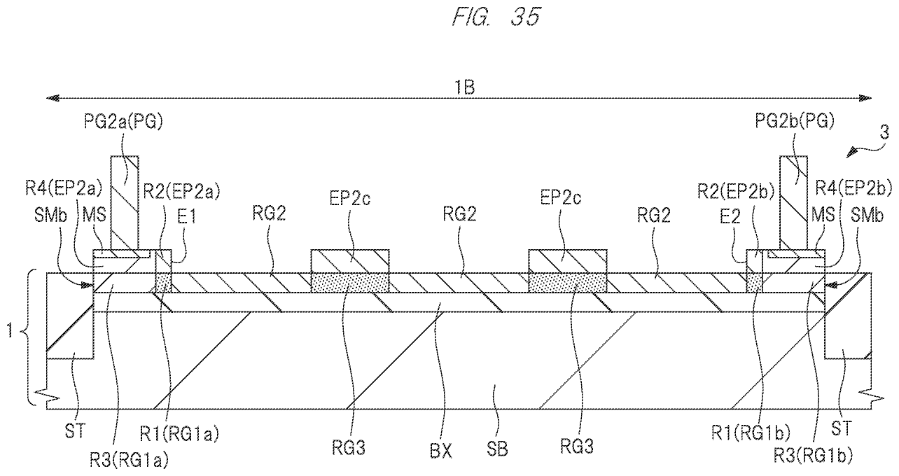

A method for obtaining a structure of FIG. 30 will be described with reference to FIGS. 31 to 33. FIGS. 31 to 33 are cross-sectional views of a main portion of a semiconductor device of a modification example of the present embodiment during the manufacturing process thereof. FIG. 31 corresponds to the same process as that of FIG. 15 mentioned above, FIG. 32 corresponds to the same process as that of FIG. 16 mentioned above, and FIG. 33 corresponds to the same process as that of FIG. 17 mentioned above.

In the case of the modification example, as shown in FIG. 31, the insulating film pattern ZMP1 formed by etching the above-mentioned insulating film ZM1 has a trailing portion SH on an outer peripheral side surface. The trailing portion SH is a portion in which a lower portion of the side surface of the insulating film pattern ZMP1 protrudes (projects) outward. This can be realized by adjusting the etching conditions for the above-mentioned insulating film ZM1. For example, an overetching amount in etching the insulating film ZM1 is reduced.

When the semiconductor layer EP is formed by an epitaxial growth method in a state in which the insulating film pattern ZMP1 has the trailing portion SH, the semiconductor layer EP (semiconductor portions EP2a and EP2b) is formed so as to cover the trailing portion SH of the insulating film pattern ZMP1, as shown in FIG. 32. Thereafter, when the sidewall spacers SW1 and the insulating film pattern ZMP1 are removed by etching, as shown in FIG. 33, the gap SK is formed between the semiconductor portion EP2b and the underlying semiconductor layer SMb in the vicinity of the end E2 of the semiconductor portion EP2b and the gap SK is formed between the semiconductor portion EP2a and the underlying semiconductor layer SMb in the vicinity of the end E1 of the semiconductor portion EP2a. The region where the trailing portion SH has been present becomes the gap SK. Thereafter, when the above-mentioned insulating film pattern ZMP2 is formed, the gap SK is filled with the insulating film pattern ZMP2.

### Second Embodiment

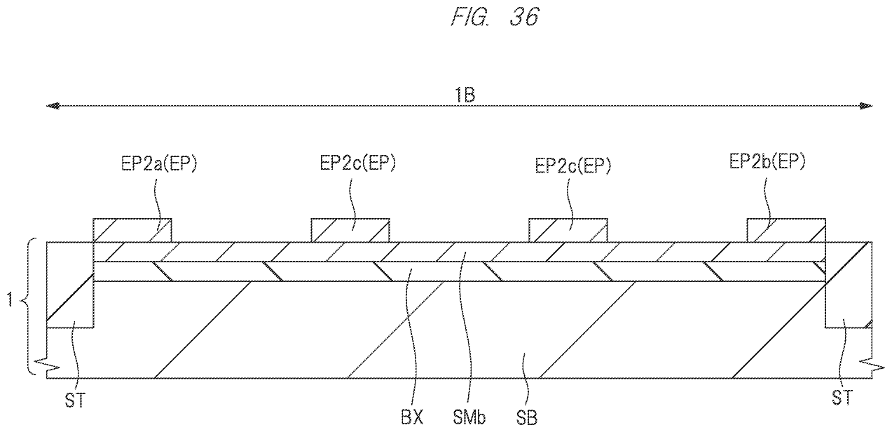

FIG. 34 is a plan view of a main portion of a semiconductor device according to a second embodiment, and FIG. 35 is a cross-sectional view of the main portion of the semiconductor device of the second embodiment. A plan view (FIG. 34) and a cross-sectional view (FIG. 35) of the resistance element formation region 1B are shown. A cross-sectional view at a location of line G-G in FIG. 34 substantially corresponds to FIG. 35. However, in FIG. 35, the above-mentioned insulating films L1 and L2, insulating film pattern ZMP2, and wiring M1 are omitted for the sake of simplification.

A difference point between the semiconductor device of the second embodiment and the semiconductor device of the first embodiment will be described below with reference to FIGS. 34 and 35.

In a second embodiment, in the resistance element formation region 1B, the semiconductor layer EP formed on the semiconductor layer SMb has not only the semiconductor portions EP2a and EP2b but also one or more semiconductor portions EP2c. In a case of FIGS. 34 and 35, two semiconductor portions EP2c are provided, but the number of semiconductor portions EP2c may be one, or three or more.

The semiconductor portion EP2c is formed on the semiconductor layer SMb, is spaced apart from the semiconductor portions EP2a and EP2b, and is arranged between the semiconductor portion EP2a and the semiconductor portion EP2b. When a plurality of semiconductor portions EP2c are provided, the plurality of semiconductor portions EP2c are arranged apart from each other. Conductivity types of the semiconductor layer SMb and the semiconductor portions EP2a, EP2b, and EP2c are the same as each other, and are p-types here.

With the provision of the semiconductor portion EP2c, in the resistance element formation region 1B, the semiconductor layer SMb has not only the above-mentioned regions RG1a, RG1b, and RG2 but also a region (connection portion) RG3 on which the semiconductor portion EP2c is formed. Since the region RG3 of the semiconductor layer SMb is the region located directly under the semiconductor portion EP2c, the number of the regions RG3 and the number of the semiconductor portions EP2c are the same. Since the semiconductor portion EP2c is arranged between the semiconductor portion EP2a and the semiconductor portion EP2b, in the semiconductor layer SMb, the region RG3 is arranged between the regions RG1a and RG1b apart from the regions RG1a and RG1b. That is, the region RG3 exists halfway in the region RG2 (element portion) of the semiconductor layer SMb.

An impurity concentration (p-type impurity concentration) in the region RG3 of the semiconductor layer SMb is lower than the impurity concentration (p-type impurity concentration) in the region RG2 of the semiconductor layer SMb. Also, the impurity concentration (p-type impurity concentration) in the semiconductor portion EP2c is higher than the impurity concentration (p-type impurity concentration) in the region RG3 of the semiconductor layer SMb. More specifically, the impurity concentration (p-type impurity concentration) in the region RG3 of the semiconductor layer SMb is the same as the impurity concentration (p-type impurity concentration) in the above-mentioned low concentration region R1, and the impurity concentration (p-type impurity concentration) in the semiconductor portion EP2c is the same as the impurity concentration (p-type impurity concentration) in the region RG2 of the semiconductor layer SMb. Incidentally, the term “same” as used herein means that two or more objects to be compared (here, “impurity concentration”) are substantially the same. That is, it means that the two or more objects to be compared are the same in the design, but are not necessarily the same in the actual manufactured products due to the manufacturing variations.

Each of the semiconductor portions EP2a and EP2b has the plug PG arranged thereon and is electrically connected to the plug PG, but the plug PG is not arranged on the semiconductor portion EP2c and is not connected to the semiconductor portion EP2c.

Other configurations of the semiconductor device according to the second embodiment are substantially the same as those of the semiconductor device according to the first embodiment, so that a repetitive description thereof will be omitted here.

Next, a difference point between the manufacturing process of the semiconductor device of the second embodiment and the above-mentioned manufacturing process of the first embodiment (FIGS. 11 to 26) will be described with reference to FIGS. 36 to 39. FIGS. 36 to 39 are cross-sectional views of the main portion of the semiconductor device of the second embodiment during the manufacturing process thereof, and show a cross-section corresponding to FIG. 35 mentioned above.

FIG. 36 is a cross-sectional view in the same process as that of FIG. 17 mentioned above. In the present second embodiment, when the semiconductor layer EP is formed by epitaxial growth, the semiconductor portions EP2a, EP2b, and EP2c are formed on the semiconductor layer SMb in the resistance element formation region 1B, as shown in FIG. 36.

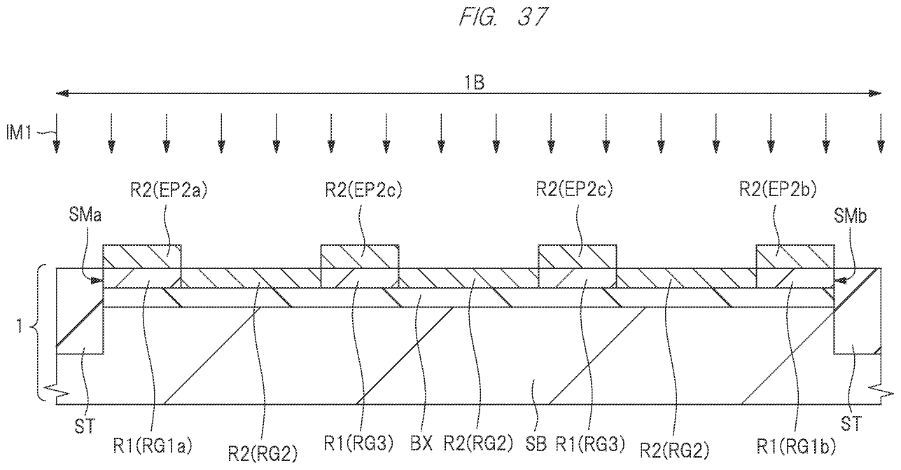

FIG. 37 is a cross-sectional view in the same process as that in FIG. 18 mentioned above. In the present second embodiment, when the above-mentioned ion implantation IM1 for forming the p⁻-type semiconductor region EX is performed, the p-type impurity is implanted into the semiconductor layers EP (respective semiconductor portions EP2a, EP2b, EP2c) and the region RG2 of the semiconductor layer SMb, which is not covered with the semiconductor layer EP (respective semiconductor portions EP2a, EP2b, and EP2c). In the ion implantation IM1, the p-type impurity is hardly introduced into the respective regions RG1a, RG1b, and RG3 of the semiconductor layer SMb, whih are covered with the semiconductor layer EP (respective semiconductor portions EP2a, EP2b, and EP2c) in the resistance element formation region 1B. At the stage where the ion implantation IM1 is performed, substantially the entirety of each of the semiconductor portions EP2a, EP2b, and EP2c in the resistance element formation region 1B becomes the medium concentration region R2. Then, substantially the entirety region RG2 of the semiconductor layer SMb in the resistance element formation region 1B, which is not covered with the semiconductor layer EP (respective semiconductor portions EP2a, EP2b, and EP2c) becomes the same impurity concentration as the medium concentration region R2, and substantially the entirety of the regions RG1a, RG1b, and RG3 of the semiconductor layer SMb in the resistance element formation region 1B, which is covered with the semiconductor layer EP (respective semiconductor portions EP2a, EP2b, and EP2c) becomes the low concentration region R1.

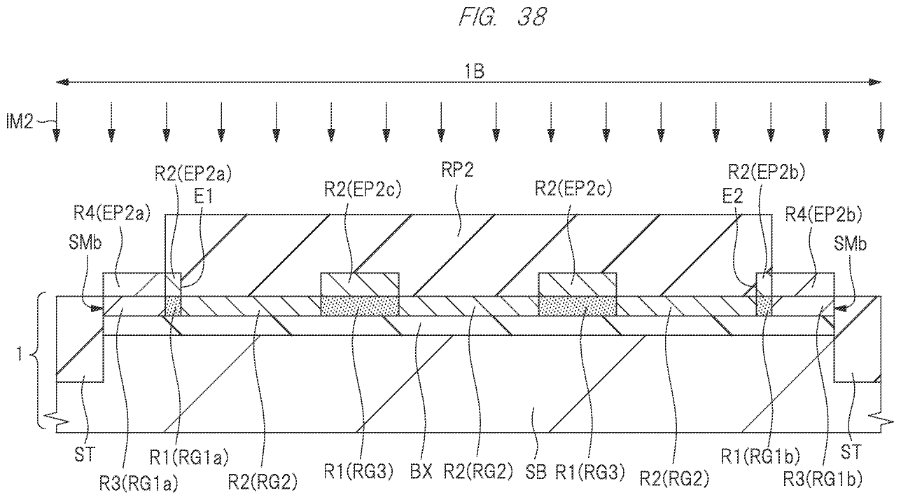

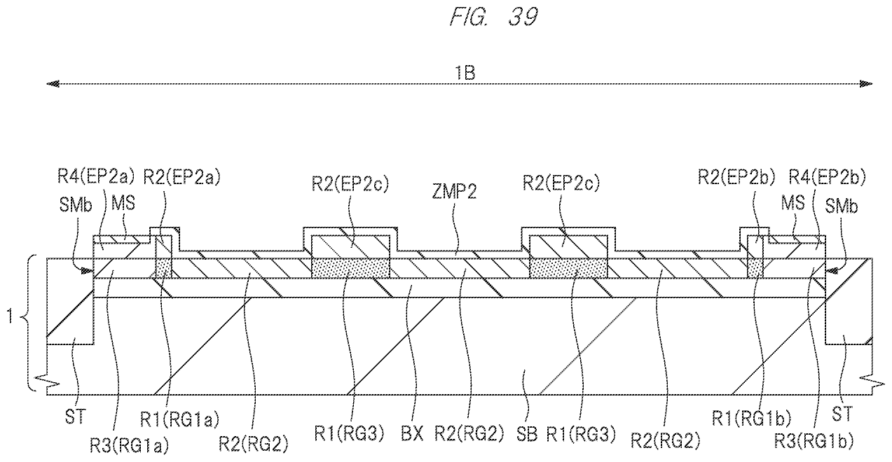

FIG. 38 is a cross-sectional view in the same process as that in FIG. 21 mentioned above. In the second embodiment, the semiconductor portion EP2c is also covered with the photoresist pattern RP2. When the above-described ion implantation IM2 for forming the p⁺-type semiconductor region SD is performed, the p-type impurity is not implanted into the semiconductor portion EP2c and the region RG3 of the underlying semiconductor layer SMb in the resistance element formation region 1B since the semiconductor portion EP2c is covered with the photoresist pattern RP2. Regarding the process other than that, the present embodiment is also the same as FIG. 24 of the first embodiment.

FIG. 39 is a cross-sectional view in the same process as that in FIG. 24 mentioned above. In the second embodiment, the semiconductor portion EP2c is covered with the insulating film pattern ZMP2. Consequently, when the metal silicide layer MS is formed by a salicide technique, the metal silicide layer MS is not formed on the surface of the semiconductor portion EP2c. Regarding the process other than that, the second embodiment is also the same as FIG. 24 of the first embodiment.

In the case of the resistance element 3 of the second embodiment, the impurity concentration (p-type impurity concentration) of the region RG3 located under the semiconductor portion EP2c is lower than the impurity concentration (p-type impurity concentration) of the region RG2 (the region not covered with the semiconductor layer EP) of the semiconductor layer SMb. Then, the impurity concentration (p-type impurity concentration) of the semiconductor portion EP2c is higher than the impurity concentration (p-type impurity concentration) of the region RG3 of the semiconductor layer SMb. Specifically, the impurity concentration (p-type impurity concentration) of the region RG3 of the semiconductor layer SMb is the same as the impurity concentration (p-type impurity concentration) of the low concentration regions R1 of the regions RG1a and RG1b of the semiconductor layer SMb, and the impurity concentration (p-type impurity concentration) of the semiconductor portion EP2c is the same as the impurity concentration (p-type impurity concentration) of the medium concentration regions R2 of the semiconductor portions EP2a and EP2b. Incidentally, the term “same” as used herein means that two or more objects to be compared (here, “impurity concentration”) are substantially the same. That is, it means that the two or more objects to be compared are the same in the design, but are not necessarily the same in the actual manufactured products due to the manufacturing variations.

Therefore, the current flowing in the semiconductor portion EP2c and the region RG3 in the resistance element 3 and in the vicinity thereof is as follows. That is, the current that has passed through the region RG2 of the semiconductor layer SMb mainly flows toward the semiconductor portion EP2c while avoiding the region RG3 of the semiconductor layer SMb. Then, the current that has passed through the semiconductor portion EP2c flows toward the region RG2 of the semiconductor layer SMb while avoiding the region RG3 of the semiconductor layer SMb, and flows in the region RG2 of the semiconductor layer SMb. As a result, the resistance of the resistance element 3 is further increased.

For this reason, the resistance of the resistance element 3 can be made larger when the semiconductor portion EP2c and the region RG3 are provided (the second embodiment) than when the semiconductor portion EP2c and the region RG3 are not provided (the first embodiment). Consequently, in the second embodiment, the resistance value of the resistance element 3 can be further increased without changing the dimensions of the resistance element 3. Thus, the resistance value of the resistance element 3 can be further increased without increasing the area required for arranging the resistance element 3 in the semiconductor device and, therefore, without inviting the increase in the area of the semiconductor device, so that this is more advantageous for the miniaturization (reduction in area) of the semiconductor device.

Also, since the plug PG is not connected to the semiconductor portion EP2c, what corresponds to the high concentration region R4 is not formed in the semiconductor portion EP2c.

Further, in the above-mentioned first embodiment, the length D1 corresponds to the interval between the semiconductor portion EP2a and the semiconductor portion EP2b, and the length D1 has been preferably 5 μm or less.

In the present second embodiment, an interval D2 between the semiconductor portions EP2a, EP2b, and EP2c is preferably 5 μm or less. That is, in the present second embodiment, the region RG2 of the semiconductor layer SMb is divided into a plurality of regions by the semiconductor portion EP2c and the region RG3 therebelow, and each length (length along the current direction, here, length in the X direction) of the plurality of regions is preferably 5 μm or less.

### Third Embodiment

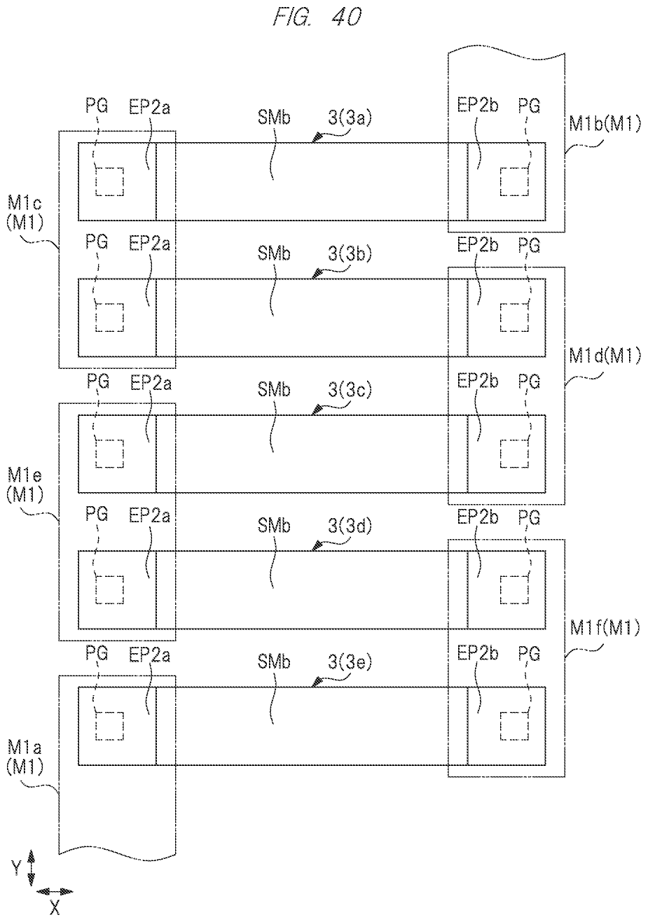

FIG. 40 is a plan view of a main portion of a semiconductor device according to a third embodiment, and shows a plan view of the resistance element formation region.

In a third embodiment, a plurality of resistance elements 3 are formed, and the plurality of resistance elements 3 are connected in series by the wirings M1 (wirings M1a, M1b, M1c, M1d, M1e, and M1f shown in FIG. 40). FIG. 40 shows a case where the five resistance elements 3 are connected in series, but the number of resistance elements 3 connected in series can be changed. In FIG. 5, the five resistance elements 3 are referred to as a resistance element 3a, a resistance element 3b, a resistance element 3c, a resistance element 3d, and a resistance element 3e in order from the top of FIG. 40.

The respective resistance elements 3a, 3b, 3c, 3d, 3e have the same structure. Further, each of the resistance elements 3a, 3b, 3c, 3d, 3e has the same structure as the resistance element 3 of the first embodiment. The resistance elements 3a, 3b, 3c, 3d, 3e each extend in the X direction and are arranged in the Y direction. The semiconductor portion EP2a of the resistance element 3a and the semiconductor portion EP2a of the resistance element 3b are electrically connected to each other via the plug PG and the wiring M1c, and the semiconductor portion EP2b of the resistance element 3b and the semiconductor portion EP2b of the resistance element 3c are electrically connected to each other via the plug PG and the wiring M1d. In addition, the semiconductor portion EP2a of the resistance element 3c and the semiconductor portion EP2a of the resistance element 3d are electrically connected to each other via the plug PG and the wiring M1e, and the semiconductor portion EP2b of the resistance element 3d and the semiconductor portion EP2b of the resistance element 3e are electrically connected to each other via the plug PG and the wiring M1f. Moreover, the semiconductor portion EP2b of the resistance element 3a is electrically connected to the wiring M1b via the plug PG, and the semiconductor portion EP2a of the resistance element 3e is electrically connected to the wiring M1a via the plug PG. Consequently, the resistance element 3a, the resistance element 3b, the resistance element 3c, the resistance element 3d, and the resistance element 3e are connected in series between the wiring M1b and the wiring M1a, and the resistance element 3 having the large resistance value can be formed by their entirety. For example, when a low voltage is applied to the semiconductor portion EP2a of the resistance element 3e from the wiring M1a via the plug PG and when a higher voltage than the low voltage is applied to the semiconductor portion EP2b of the resistance element 3a from the wiring M1b via the plug PG, the current flows in the wiring M1a through the resistance elements 3a, 3b, 3c, 3d, 3e in order from the wiring M1b.

### Fourth Embodiment

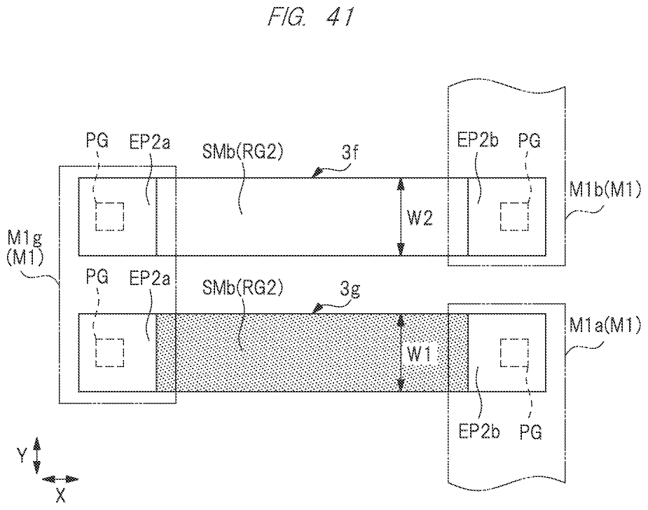

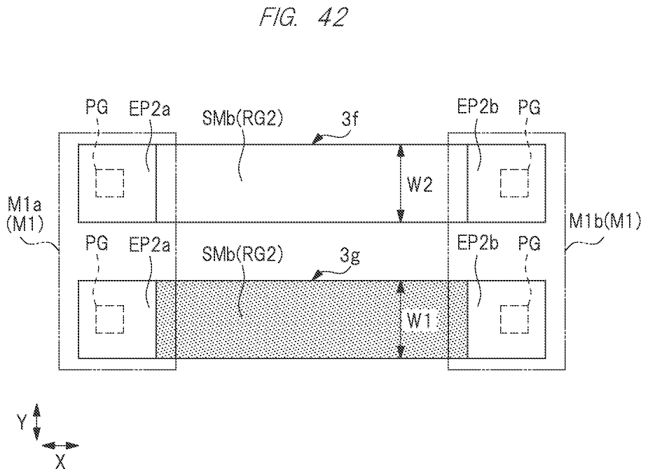

Each of FIGS. 41 and 42 is a plan view of a main portion of a semiconductor device according to a fourth embodiment, and shows a plan view of a resistance element formation region.

FIGS. 41 and 42 each show a resistance element 3f and a resistance element 3g. The resistance element 3f has the same structure as the resistance element 3 of the first embodiment. Consequently, the semiconductor layer SMb configuring the resistance element 3f is made of a single crystal semiconductor (for example, single crystal silicon).

The resistance element 3g of the fourth embodiment has a structure similar to that of the resistance element 3 of the first embodiment, and is comprised of the semiconductor layer SMb and the above-mentioned semiconductor portions EP2a and EP2b. However, unlike the resistance element 3f, the region RG2 (the region not covered with the semiconductor layer EP) of the semiconductor layer SMb configuring the resistance element 3g is made of a polycrystalline semiconductor (for example, polycrystalline silicon). In FIG. 41, the semiconductor layer SMb made of a polycrystalline semiconductor is hatched with dots for easy understanding.

A polycrystalline semiconductor region of the resistance element 3g (that is, the region RG2 of the semiconductor layer SMb) can be formed by damaging the semiconductor layer SMb made of a single crystal by ion implantation and changing the single crystal region into the polycrystalline region due to the damage. In the ion implantation for polycrystallization, the resistance element 3f may be covered with the photoresist pattern. This makes it possible to prevent the semiconductor layer SMb configuring the resistance element 3f from being polycrystallized.

In a case of FIG. 41, the resistance element 3f and the resistance element 3g are connected in series. Specifically, the semiconductor portion EP2a of the resistance element 3f and the semiconductor portion EP2a of the resistance element 3g are electrically connected to each other via the plug PG and the wiring M1g. Further, the semiconductor portion EP2b of the resistance element 3f is electrically connected to the wiring M1b via the plug PG, and the semiconductor portion EP2b of the resistance element 3g is electrically connected to the wiring M1a via the plug PG. Consequently, the resistance element 3f and the resistance element 3g are connected in series between the wiring M1a and the wiring M1b. For example, when the low voltage is applied to the semiconductor portion EP2b of the resistance element 3g from the wiring M1a via the plug PG and when the higher voltage than the low voltage is applied to the semiconductor portion EP2b of the resistance element 3f from the wiring M1a via the plug PG, the current flows in the wiring M1a from the wiring M1b through the resistance elements 3f and 3g in order.

Meanwhile, in a case of FIG. 42, the resistance element 3f and the resistance element 3g are connected in parallel. Specifically, the semiconductor portion EP2a of the resistance element 3f and the semiconductor portion EP2a of the resistance element 3g are electrically connected to each other via the plug PG and the wiring M1a, and the semiconductor portion EP2b of the resistance element 3f and the semiconductor portion EP2a of the resistance element 3g are electrically connected to each other via the plug PG and the wiring M1b. Consequently, the resistance element 3f and the resistance element 3g are connected in parallel between the wiring M1a and the wiring M1b. For example, when the low voltage is applied to the semiconductor portion EP2b of each of the resistance elements 3f and 3g from the wiring M1b via the plugs PG and when the higher voltage than the low voltage is applied to the semiconductor portion EP2b of each of the resistance elements 3f and 3g from the wiring M1a via the plugs PG, the current flows in the wiring M1b via both of a path passing from the wiring M1a to the resistance element 3g and a path passing from the wiring M1a to the resistance element 3f.

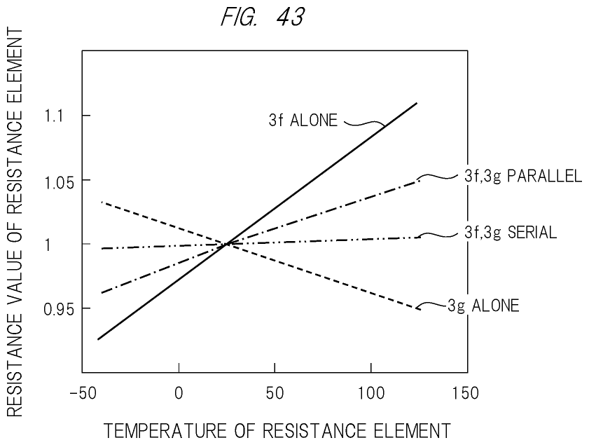

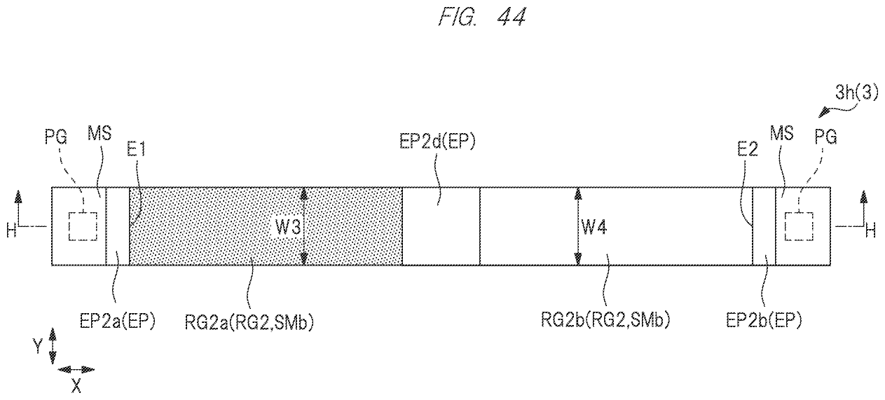

FIG. 43 is a graph showing temperature dependence of the resistance value of the resistance element. A horizontal axis of the graph of FIG. 43 corresponds to the temperature of the resistance element, and a vertical axis of the graph of FIG. 43 corresponds to the resistance value of the resistance element. The resistance value on the vertical axis of the graph of FIG. 43 is normalized by the resistance value at 27° C. Further, in the graph of FIG. 43, a solid line shows a case of the resistance element 3f alone, a dotted line shows a case of the resistance element 3g alone, and a single-dotted line shows a case where the resistance element 3f and the resistance element 3g are connected in parallel (in a case of FIG. 42), and a double-dotted line shows a case where the resistance element 3f and the resistance element 3g are connected in series (in a case of FIG. 41).

Since the semiconductor layer SMb configuring the resistance element 3f is made of a single crystal semiconductor (for example, single crystal silicon), the resistance value of the resistance element 3f has positive temperature dependence. Meanwhile, since the region RG2 of the semiconductor layer SMb configuring the resistance element 3g is made of a polycrystalline semiconductor (for example, polycrystalline silicon), the resistance value of the resistance element 3g has negative temperature dependence. Here, the positive temperature dependence corresponds to a case where the resistance value increases as the temperature rises, and the negative temperature dependence corresponds to a case where the resistance value decreases as the temperature rises.

Namely, the resistance element 3f and the resistance element 3g have the opposite temperature dependencies of the resistance values. This is because the temperature dependence of the resistance of the single crystal semiconductor (for example, single crystal silicon) and the temperature dependence of the resistance of the polycrystalline semiconductor (for example, polycrystalline silicon) become reversed.

When the resistance element 3f and the resistance element 3g are connected in series, the temperature dependence of the resistance of the resistance element 3f and the temperature dependence of the resistance of the resistance element 3g act so as to cancel each other out. For this reason, as can be seen from the graph of FIG. 43, a resistance temperature coefficient of the resistance element comprised of the resistance elements 3f and 3g connected in series can be made smaller than the resistance temperature coefficient of the resistance element 3f alone and the resistance temperature coefficient of the resistance element 3g alone. Further, as can be seen from the graph of FIG. 43, (an absolute value of) the resistance temperature coefficient of the resistance element configuring the resistance elements 3f and 3g connected in parallel can be made smaller than (an absolute value of) the resistance temperature coefficient of the resistance element 3f alone and (an absolute value of) the resistance temperature coefficient of the resistance element 3g alone. Here, the resistance temperature coefficient corresponds to a coefficient that indicates a rate at which the resistance changes per temperature of 1° C., and a slope of the graph in FIG. 43 approximately corresponds to the resistance temperature coefficient. The above-mentioned positive temperature dependence means that the resistance temperature coefficient is a positive value, and the above-mentioned negative temperature dependence means that the resistance temperature coefficient is a negative value.

In the fourth embodiment, by connecting the resistance element 3f and the resistance element 3g in series or in parallel, (the absolute value of) the resistance temperature coefficient of the entire resistance element can be reduced, so that it is possible to suppress or prevent the fluctuations in the resistance value of the resistance element due to a factor such as a change in environment temperatures of the semiconductor device or a temperature change of the semiconductor device caused by heat generation. This makes it possible to realize the high performance (improvement in temperature drift) of the semiconductor device. Further, as can be seen from the graph of FIG. 43, (the absolute value of) the resistance temperature coefficient of the entire resistance element is further reduced when the resistance elements 3f and 3g are connected in series than when the resistance elements 3f and 3g are connected in parallel.

Also, the polycrystalline semiconductor (for example, polycrystalline silicon) is fused easier than the single crystal semiconductor (for example, single crystal silicon) when a large current flows. That is, the polycrystalline semiconductor has a smaller fusing current than the single crystalline semiconductor. Here, the fusing current corresponds to a lower limit value of a current at which fusing can occur. Therefore, the resistance element 3g having a polycrystalline region tends to have the lower fusing current than the resistance element 3f having no polycrystalline region.

Consequently, in the fourth embodiment, a width W1 (dimension in the Y direction) of the region RG2 of the semiconductor layer SMb configuring the resistance element 3g is preferably 0.2 μm or more (W1≥0.2 μm), more preferably 0.2 μm or more and 1.0 μm or less (1.0 μm≥W1≥0.2 μm), further more preferably 0.5 μm or more and 1.0 μm or less (1.0 μm≥W1≥0.5 μm). Thus, the fusing current of the resistance element 3g having the polycrystalline region can be increased to some extent, so that a risk of fusing the resistance element 3g having the polycrystalline region when the large current flows can be reduced. Therefore, the reliability of the semiconductor device can be further improved.

Meanwhile, since the resistance element 3f does not have the polycrystalline region, a fusing phenomenon is less likely to occur. Consequently, in the fourth embodiment, a width W2 (dimension in the Y direction) of the region RG2 of the semiconductor layer SMb configuring the resistance element 3f may be smaller than the width W1 of the region RG2 of the semiconductor layer SMb configuring the resistance element 3g and is permitted also at 0.2 μm or less.

### Fifth Embodiment

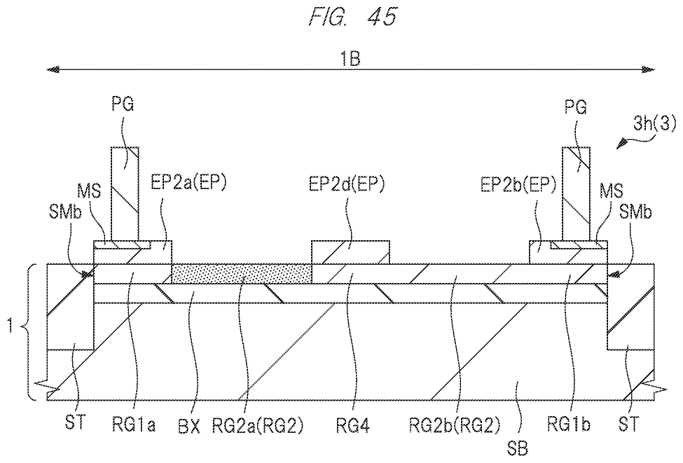

FIGS. 44 and 45 are a plan view (FIG. 44) and a cross-sectional view (FIG. 45) of a semiconductor device according to a fifth embodiment, and show the plan view and the cross-sectional view of the resistance element formation region 1B in which the resistance element 3 is formed. The cross-sectional view located at line H-H in FIG. 44 substantially corresponds to FIG. 45. However, in FIG. 45, the above-mentioned insulating films L1 and L2, insulating film pattern ZMP2, and wiring M1 are omitted in figures for the sake of simplification. Further, the resistance element 3 shown in FIGS. 44 and 45 is hereinafter referred to as a resistance element 3h.

The resistance element 3h shown in FIGS. 44 and 45 is similar to the resistance element 3 of the first embodiment, but differs from the resistance element 3 of the first embodiment in the following points.

In a case of FIGS. 44 and 45, the semiconductor layer EP formed on the semiconductor layer SMb in the resistance element formation region 1B has not only the semiconductor portions EP2a and EP2b but also the semiconductor portion EP2d. That is, the semiconductor portion EP2a, the semiconductor portion EP2b, and the semiconductor portion EP2d are formed on the semiconductor layer SMb, and the semiconductor portion EP2a, the semiconductor portion EP2b, and the semiconductor portion EP2d are spaced apart from each other. The semiconductor portion EP2d is spaced apart from the semiconductor portions EP2a and EP2b and arranged between the semiconductor portion EP2a and the semiconductor portion EP2b.

With the provision of the semiconductor portion EP2d, in the resistance element formation region 1B, the semiconductor layer SMb has not only the regions RG1a, RG1b, and RG2 but also a region (connection portion) RG4 on which the semiconductor portion EP2d is formed. The region RG4 of the semiconductor layer SMb is a region located directly under the semiconductor portion EP2d. Since the semiconductor portion EP2d is arranged between the semiconductor portion EP2a and the semiconductor portion EP2b, in the semiconductor layer SMb, the region RG4 is spaced apart from the regions RG1a and RG1b and is arranged between the regions RG1a and RG1b. That is, the region RG4 exists halfway in the region RG2 (element portion) of the semiconductor layer SMb. Consequently, the region RG2 of the semiconductor layer SMb is divided into two regions RG2a and RG2b by the semiconductor portion EP2c and the region RG4 therebelow. A portion of the region RG2 of the semiconductor layer SMb, which is located between the regions RG1a and RG4, corresponds to the region RG2a, and a portion of the region RG2 of the semiconductor layer SMb, which is located between the regions RG1b and RG4, corresponds to the region RG2b.

The region RG2a (corresponding to a region hatched with dots in FIGS. 44 and 45) located between the region RG1a and the region RG4 in the region RG2 of the semiconductor layer SMb is made of a polycrystalline semiconductor (for example, polycrystalline silicon). Further, the region RG2b located between the region RG1b and the region RG4 in the region RG2 of the semiconductor layer SMb is made of a single crystal semiconductor (for example, single crystal silicon). That is, the region RG2 (a region not covered with the semiconductor layer EP) of the semiconductor layer SMb configuring the resistance element 3h has the region RG2a made of polycrystal and the region RG2b made of single crystal, and the region RG2a made of polycrystal and the region RG2b made of single crystal are connected in series between the region RG1a and the region RG1b. Incidentally, the region RG4 located under the semiconductor portion EP2d is interposed between the region RG2a made of polycrystalline and the region RG2b made of single crystalline. The region RG4 may be made of a single crystal semiconductor or a polycrystalline semiconductor, but here the region RG4 is made of a single crystal semiconductor (for example, single crystal silicon).

In the fifth embodiment, the resistance of the region RG2a made of polycrystalline has the negative temperature dependence, and the resistance of the region RG2b made of single crystal has the positive temperature dependence. Consequently, the region RG2a made of polycrystalline and the region RG2b made of single crystalline have the opposite temperature dependencies of the resistance value. As a result, the temperature dependence of the resistance of the region RG2a made of polycrystal and the temperature dependence of the resistance of the region RG2b made of single crystal act so as to cancel each other out. This makes it possible to make (the absolute value of) the temperature coefficient of the resistance of the resistance element 3h of the fifth embodiment smaller than (the absolute value of) the temperature coefficient of the resistance of the resistance element 3 of the first embodiment. For this reason, in the case of the fifth embodiment as well, it is possible to suppress or prevent the fluctuations in the resistance value of the resistance element due to the factor such as the change in the environmental temperature of the semiconductor device or the temperature changes in the semiconductor device caused by the heat generation. This makes it possible to realize the higher performance of the semiconductor device (improvement of the temperature drift).

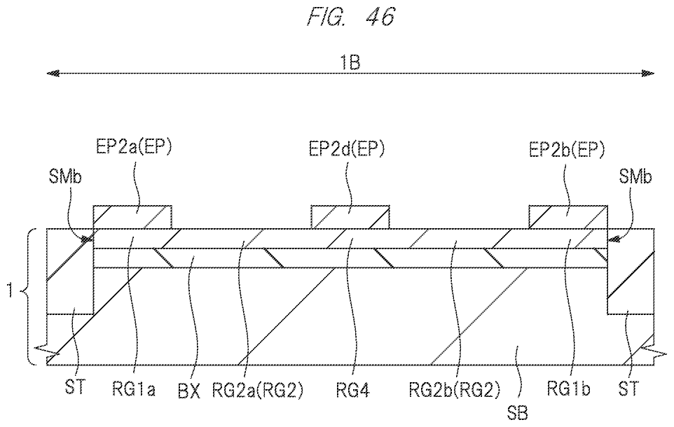

Next, a difference point between a manufacturing process of the semiconductor device of the fifth embodiment and the manufacturing process of the first embodiment (FIGS. 11 to 26) will be described below with reference to FIGS. 46 to 49. FIGS. 46 to 49 are cross-sectional views of the main portion of the semiconductor device of the fifth embodiment during the manufacturing process, and show the cross-section corresponding to FIG. 45.

FIG. 46 is a cross-sectional view in the same process as that of FIG. 17. In the fifth embodiment, when the semiconductor layer EP is formed by epitaxial growth, the semiconductor portions EP2a, EP2b, and EP2d are formed on the semiconductor layer SMb in the resistance element formation region 1B, as shown in FIG. 46.

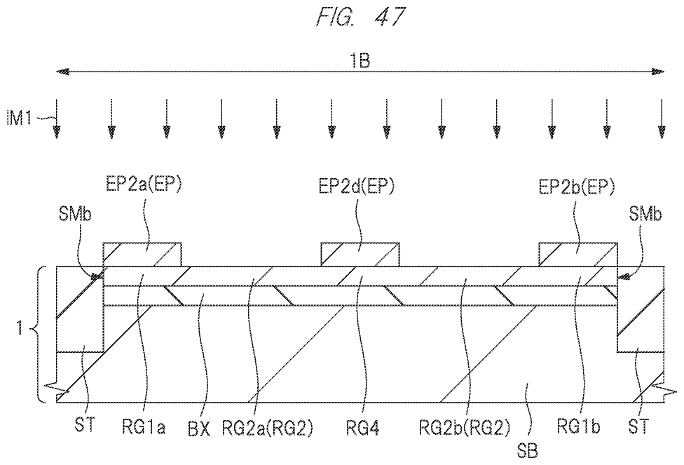

FIG. 47 is a cross-sectional view in the same process as that in FIG. 18. In the fifth embodiment, when the ion implantation IM1 for forming the p⁻ type semiconductor region EX is performed, the p-type impurity is implanted into the semiconductor layers EP (respective semiconductor portions EP2a, EP2b, EP2d) and the respective regions RG2a and RG2b of the semiconductor layer SMb, which are not covered with the semiconductor layer EP (respective semiconductor portions EP2a, EP2b, EP2d) in the resistance element formation region 1B. In this ion implantation IM1, the p-type impurity is hardly introduced into the respective regions RG1a, RG1b, RG4 of the semiconductor layer SMb, which are not covered with the semiconductor layer EP (respective semiconductor portions EP2a, EP2b, EP2d), in the resistance element formation region 1B.

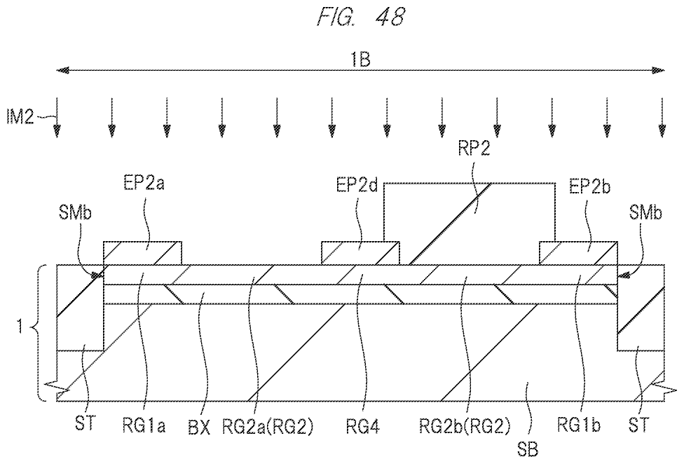

FIG. 48 is a cross-sectional view in the same process as that in FIG. 21. In the fifth embodiment, the region RG2b of the semiconductor layer SMb is covered with the photoresist pattern RP2, but the region RG2a of the semiconductor layer SMb may be exposed without being covered with the photoresist pattern RP2. When the ion implantation IM2 for forming the p⁺-type semiconductor region SD is performed, in the resistance element formation region 1B, the p-type impurity is not implanted into the region RG2b of the semiconductor layer SMb since being covered with the photoresist pattern RP2. However, the p-type impurity can be implanted into the region RG2a of the semiconductor layer SMb since being not covered with the photoresist pattern RP2 and being exposed.

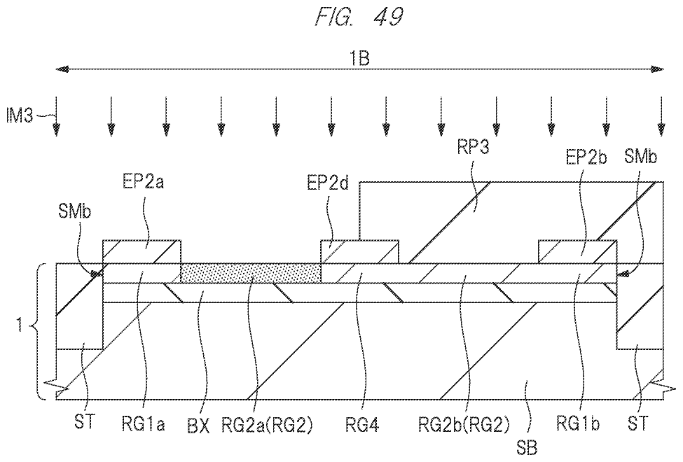

A step of FIG. 49 is not performed in the above-mentioned embodiments, and is performed after the step of FIG. 48. In the fifth embodiment, after performing the step (ion implantation IM2) of FIG. 48, the photoresist pattern RP2 is removed by ashing or the like and, then, a photoresist pattern RP3 is formed on the semiconductor layer SMb and the semiconductor layer EP in the resistance element formation region 1B by using a photolithographic technique. In the resistance element formation region 1B, the region RG2b of the semiconductor layer SMb is covered with the photoresist pattern RP3, but the region RG2a of the semiconductor layer SMb is not covered with the photoresist pattern RP3 and is exposed. Also, the MISFET formation region 1A is covered with the photoresist pattern RP3.

After forming the photoresist pattern RP3, ion implantation IM3 is performed to polycrystallize the region RG2a of the semiconductor layer SMb. In the ion implantation IM3, for example, germanium (Ge) or boron difluoride (BF₂) is ion-implanted. Since the region RG2a of the semiconductor layer SMb is damaged by the ion implantation IM3, the region RG2a of the semiconductor layer SMb made of single crystal silicon becomes amorphous. Thereafter, the region RG2a of the semiconductor layer SMb transitions from an amorphous state to a polycrystalline state by performing an annealing treatment (heat treatment) after removing the photoresist pattern RP3. Consequently, the region RG2a of the semiconductor layer SMb becomes comprised of the polycrystalline semiconductor (for example, polycrystalline silicon).

Meanwhile, since the region RG2b of the semiconductor layer SMb is covered with the photoresist pattern RP3, it is not damaged by the ion implantation IM3 and is maintained in a single crystal state. Further, since the semiconductor layers SMa and EP in the MISFET formation region 1A are covered with the photoresist pattern RP3, they are not damaged by the ion implantation IM3 and are maintained in a single crystal state.

Thereafter, also in the fifth embodiment, the insulating film pattern ZMP2 formation step and the metal silicide layer MS are performed, but their descriptions will be omitted here. Incidentally, in the fifth embodiment, the semiconductor portion EP2d is covered with the insulating film pattern ZMP2, so that the metal silicide layer MS is not formed on the surface of the semiconductor portion EP2d if the metal silicide layer MS is formed by a salicide technique.

Also, as described also in the fourth embodiment, the polycrystalline semiconductor (for example, polycrystalline silicon) is fused easier than the single crystalline semiconductor (for example, single crystalline silicon) when the large current flows therein.

Consequently, in the fifth embodiment, a width W3 (dimension in the Y direction) of the region RG2a (polycrystalline region) of the semiconductor layer SMb configuring the resistance element 3h is 0.2 μm or more (W3≥0.2 μm), more preferably 0.2 μm or more and 1.0 μm or less (1.0 μm≥W3≥0.2 μm), further more preferably 0.5 μm or more and 1.0 μm or less (1.0 μm≥W3≥0.2 μm). Thus, the fusing current of the polycrystalline region (region RG2a), which the resistance element 3h has, can be increased to some extent, so that the risk of fusing the polycrystalline region (region RG2a) when the large current flows therein can be reduced. Therefore, the reliability of the semiconductor device can be further improved.

Meanwhile, since the region RG2b of the semiconductor layer SMb configuring the resistance element 3h is the single crystal region instead of the polycrystal region, the fusing phenomenon is less likely to occur. Therefore, in the fifth embodiment, a width W4 (dimension in the Y direction) of the region RG2b of the semiconductor layer SMb configuring the resistance element 3h may be smaller than the width W3 of the region RG2a (polycrystalline region) of the semiconductor layer SMb configuring the resistance element 3h, and is permitted also at 0.2 μm or less. However, in the resistance element 3h, if the width W4 of the region RG2b of the semiconductor layer SMb is the same as the width W3 of the region RG2a (polycrystalline region) of the semiconductor layer SMb, the present embodiment can obtain an advantage of easily forming the resistance element 3h.

Although the invention made by the present inventor(s) has been specifically described based on the embodiments, the present invention is not limited to the above-mentioned embodiments and, needless to say, can be variously modified without departing from the scope of the invention.

What is claimed is:

1. A semiconductor device comprising:
a substrate;
a resistance element formed in a first region of the substrate; and
a MISFET formed in a second region of the substrate,
wherein the substrate has:
a support substrate;
an insulating layer on the support substrate; and
a semiconductor layer on the insulating layer,
wherein the resistance element is comprised of:
the semiconductor layer located in the first region; and
an epitaxial semiconductor layer formed on the semiconductor layer located in the first region,
wherein the epitaxial semiconductor layer has:
a first semiconductor portion formed on the semiconductor layer located in the first region; and
a second semiconductor portion formed on the semiconductor layer located in the first region, and spaced apart from the first semiconductor portion,
wherein the semiconductor layer located in the first region has:
a first connection portion on which the first semiconductor portion is formed;
a second connection portion on which the second semiconductor portion is formed; and
an element portion located between the first connection portion and the second connection portion and, on which no epitaxial semiconductor layer is formed,
wherein a conductivity type of each of the first semiconductor portion, the second semiconductor portion, the first connection portion, the second connection portion, and the element portion is a first conductivity type,
wherein each of the first connection portion and the second connection portion further has a first low concentration region of the first conductivity type, which is located next to the element portion,
wherein each of the first semiconductor portion and the second semiconductor portion further has a first medium concentration region of the first conductivity type, which is located the first low concentration region,
wherein an impurity concentration of the first low concentration region of each of the first connection portion and the second connection portion is lower than an impurity concentration of the element portion, and
wherein an impurity concentration of the first medium concentration region of each of the first semiconductor portion and the second semiconductor portion is higher than the impurity concentration of the first low concentration region of each of the first connection portion and the second connection portion.

2. The semiconductor device according to claim 1,
wherein the first medium concentration region and the element portion have the same impurity concentration as each other.

3. The semiconductor device according to claim 1,
wherein a metal silicide layer is formed on a surface of each of the first semiconductor portion and the second semiconductor portion.

4. The semiconductor device according to claim 3,
wherein each of the first connection portion and the second connection portion further has a first high concentration region of the first conductivity type, which is located next to the first low concentration region,
wherein each of the first semiconductor portion and the second semiconductor portion further has a second high concentration region of the first conductivity type, which is located on the first high concentration region,
wherein an impurity concentration of the first high concentration region of each of the first connection portion and the second connection portion is higher than the impurity concentration of the first medium concentration region of each of the first semiconductor portion and the second semiconductor portion,
wherein an impurity concentration of the second high concentration region of each of the first semiconductor portion and the second semiconductor portion is higher than the impurity concentration of the first medium concentration region of each of the first semiconductor portion and the second semiconductor portion,
wherein the first low concentration region is interposed between the element portion and the first high concentration region of each of the first connection portion and the second connection portion, and
wherein the metal silicide layer is formed on a surface of the second high concentration region.

5. The semiconductor device according to claim 4,
wherein the first high concentration region and the second high concentration region have the same impurity concentration as each other.

6. The semiconductor device according to claim 1, further comprising an element isolation region formed in the substrate, penetrating through the semiconductor layer and the insulating layer, and having a bottom portion reaching the support substrate,
wherein the semiconductor layer located in the first region is surrounded by the element isolation region in a plan view.

7. The semiconductor device according to claim 6,
wherein the semiconductor layer located in the second region is surrounded by the element isolation region in the plan view, and
wherein the semiconductor layer located in the first region and the semiconductor layer located in the second region are spaced apart from each other by the element isolation region.

8. The semiconductor device according to claim 1,
wherein the epitaxial semiconductor layer is formed also on the semiconductor layer located in the second region,
wherein the epitaxial semiconductor layer has:
a third semiconductor portion formed on the semiconductor layer located in the second region; and
a fourth semiconductor portion formed on the semiconductor layer located in the second region, and spaced apart from the third semiconductor portion,
wherein the MISFET has a gate electrode formed on the semiconductor layer located in the second region via a gate insulating film,
wherein a source region of the MISFET is formed in the semiconductor layer and the third semiconductor portion located in the second region, and
wherein a drain region of the MISFET is formed in the semiconductor layer and the fourth semiconductor portion located in the second region.

9. The semiconductor device according to claim 8,
wherein the source region is comprised of a first low concentration source region of the first conductivity type, which is formed in the semiconductor layer, and a first high concentration source region of the first conductivity type, which is formed in the semiconductor layer and the third semiconductor portion and has an impurity concentration higher than that of the first low concentration source region, and
wherein the drain region is comprised of a first low concentration drain region of the first conductivity type, which is formed in the semiconductor layer, and a first high concentration drain region of the first conductivity type, which is formed in the semiconductor layer and the fourth semiconductor portion and has an impurity concentration higher than that of the first low concentration drain region.

10. The semiconductor device according to claim 9,
wherein an impurity concentration of each of the element portion, the first medium concentration region, the first low concentration source region, and the first low concentration drain region is the same as each other.

11. The semiconductor device according to claim 10,
wherein each of the first connection portion and the second connection portion further has a first high concentration region of the first conductivity type, which is located next to the first low concentration region,
wherein each of the first semiconductor portion and the second semiconductor portion further has a second high concentration region of the first conductivity type, which is located on the first high concentration region,
wherein the impurity concentration of the first high concentration region of each of the first connection portion and the second connection portion is higher than the impurity concentration of the first medium concentration region of each of the first semiconductor portion and the second semiconductor portion,
wherein the impurity concentration of the second high concentration region of each of the first semiconductor portion and the second semiconductor portion is higher than the impurity concentration of the first medium concentration region of each of the first semiconductor portion and the second semiconductor portion,
wherein the first low concentration region is interposed between the element portion and the first high concentration region of each of the first connection portion and the second connection portion, and
wherein the first high concentration region, the second high concentration region, the first high concentration source region, and the first high concentration drain region have the same impurity concentration as each other.

12. The semiconductor device according to claim 11,
wherein a metal silicide layer is formed on a surface of the second high concentration region.

13. The semiconductor device according to claim 8,
wherein a thickness of the element portion is thinner than a thickness of the gate electrode.

14. The semiconductor device according to claim 1,
wherein the epitaxial semiconductor layer further has a third semiconductor portion formed on the semiconductor layer located in the first region, spaced apart from the first semiconductor portion and the second semiconductor portion, and arranged between the first semiconductor portion and the second semiconductor portion,
wherein the semiconductor layer located in the first region further has a third connection portion on which the third semiconductor portion is formed,
wherein the third connection portion exists halfway in the element portion,
wherein an impurity concentration in the third connection portion is lower than the impurity concentration in the element portion, and
wherein an impurity concentration in the third semiconductor portion is higher than the impurity concentration in the third connection portion.

15. The semiconductor device according to claim 1,
wherein a gap is formed between the first semiconductor portion and the underlying semiconductor layer in a vicinity of an end of the first semiconductor portion on a side opposing the second semiconductor portion.

16. The semiconductor device according to claim 1, further comprising an interlayer insulating film formed on the substrate so as to cover the semiconductor layer and the epitaxial semiconductor layer,
wherein a plurality of conductive plugs are embedded in the interlayer insulating film, and
wherein the plurality of conductive plugs includes a first plug formed on the first semiconductor portion and electrically connected to the first semiconductor portion, and a second plug formed on the second semiconductor portion and electrically connected to the second semiconductor portion.

17. A semiconductor device comprising:
a substrate;
a first resistance element formed in a first region of the substrate;
a second resistance element formed in a second region of the substrate; and
a MISFET formed in a third region of the substrate,
wherein the substrate has:
a support substrate;
an insulating layer on the support substrate; and
a semiconductor layer on the insulating layer,
wherein the first resistance element is comprised of:
the semiconductor layer located in the first region; and
an epitaxial semiconductor layer formed on the semiconductor layer located in the first region,
wherein the second resistance element is comprised of:
the semiconductor layer located in the second region; and
the epitaxial semiconductor layer formed on the semiconductor layer located in the second region,
wherein the epitaxial semiconductor layer has:
a first semiconductor portion formed on the semiconductor layer located in the first region;
a second semiconductor portion formed on the semiconductor layer located in the first region, and spaced apart from the first semiconductor portion;
a third semiconductor portion formed on the semiconductor layer located in the second region; and
a fourth semiconductor portion formed on the semiconductor layer located in the second region, and spaced apart from the third semiconductor portion,
wherein the semiconductor layer located in the first region has:
a first connection portion on which the first semiconductor portion is formed;
a second connection portion on which the second semiconductor portion is formed; and
a first element portion located between the first connection portion and the second connection portion, and on which no epitaxial semiconductor layer is formed,
wherein the semiconductor layer located in the second region has:
a third connection portion on which the third semiconductor portion is formed;
a fourth connection portion on which the fourth semiconductor portion is formed; and
a second element portion located between the third connection portion and the fourth connection portion and, on which no epitaxial semiconductor layer is formed,
wherein the first element portion is made of single crystal,
wherein the second element portion is made of polycrystal, and
wherein the first resistance element and the second resistance element are connected in series or in parallel.

18. A semiconductor device comprising:
a substrate;
a resistance element formed in a first region of the substrate; and
a MISFET formed in a second region of the substrate,
wherein the substrate has:
a support substrate;
an insulating layer on the support substrate; and
a semiconductor layer on the insulating layer,
wherein the resistance element is comprised of:
the semiconductor layer located in the first region; and
an epitaxial semiconductor layer formed on the semiconductor layer located in the region,
wherein the epitaxial semiconductor layer has:
a first semiconductor portion formed on the semiconductor layer located in the first region; and
a second semiconductor portion formed on the semiconductor layer located in the first region, and spaced apart from the first semiconductor portion,
wherein the semiconductor located in the first region has:
a first connection portion on which the first semiconductor portion is formed;
a second connection portion on which the second semiconductor portion is formed; and
an element portion located between the first connection portion and the second connection portion and, on which no epitaxial semiconductor layer is formed,
wherein the element portion has a single crystal region made of single crystal, and a polycrystalline region made of polycrystalline, and
wherein the single crystal region and the polycrystalline region are connected in series between the first connection portion and the second connection portion.

19. The semiconductor device according to claim 18,
wherein a width of the element portion is 0.2 μm or more.
